(19) United States
(12) Patent Application Publication
(10) Pub. No.: US 2026/0086129 A1
(43) Pub. Date: Mar. 26, 2026

(54) CURRENT SENSOR COMPONENTS AND METHODS FOR PRODUCING SAME

(71) Applicant: Infineon Technologies AG, Neubiberg (DE)

(72) Inventors: Rainer Markus SCHALLER, Aichen (DE); Volker STRUTZ, Tegernheim (DE); Nagasrinivasa Rao KURETI, Bangalore (IN); Edwin Mario MOTZ, Wernberg (AT)

(21) Appl. No.: 19/338,894

(22) Filed: Sep. 24, 2025

(30) Foreign Application Priority Data
Sep. 26, 2024 (DE) 102024209345.9

(51) Int. Cl. G01R 15/20; G01R 19/00; G01R 33/00

(52) U.S. Cl. CPC G01R 15/207; G01R 19/0092; G01R 33/0011; G01R 33/0047; G01R 33/0052

(57) ABSTRACT

A current sensor component, and in particular a residual current sensor component, has a package that is formed entirely from a potting material that is exposed to the outside and constitutes an outer boundary of the package. At least one magnetic field sensor is arranged in the package. At least two current conductors have sections arranged adjacently in the package. A magnetic field concentrator at least partially surrounds the adjacently arranged sections of the at least two current conductors and is configured to concentrate a magnetic field generated by currents flowing through the at least two current conductors onto the magnetic field sensor. The magnetic field concentrator is arranged at least partially in the potting material or is mounted on an outer surface of the package.

### CROSS-REFERENCE TO RELATED APPLICATION

This application claims priority to Germany Patent Application No. 102024209345.9 filed on Sep. 26, 2024, the content of which is incorporated by reference herein in its entirety.

### BACKGROUND

The present disclosure relates to current sensor components, and in particular residual current sensor components, and methods for producing same. The present disclosure relates in particular to current sensor components, and in particular residual current sensor components, having a magnetic field concentrator that is configured to concentrate currents flowing through one or more conductors onto a magnetic field sensor of the current sensor component. Aspects of the present disclosure also relate in particular to how a magnetic field sensor and other components of the current sensor components are packaged.

Current sensor components and residual current sensor components, which are used for example as circuit breakers, are generally known. A residual current sensor here is a component that measures the difference between an outgoing electric current and a returning electric current in a circuit. It is thus possible to detect an undesired current flow, and the residual current sensor may be used for example to trigger electrical safety devices, for example circuit breakers, in order to interrupt the current supply.

Residual current monitoring requires highly sensitive components or high magnetic field strengths. Typical solutions of packaged fault sensors, as offered for example by LEM, are space-consuming and expensive. Traditional closed-circuit magnetic core-based solutions are able to be used only for AC supply fault conditions, and cannot be used to detect DC fault conditions. The use of magnetic cores based on a fluxgate is in turn space-consuming and not environmentally friendly. In the case of components with through-holes, production costs may in turn be increased at the product level.

There is therefore a need for current sensor components, in particular residual current sensor components, that are able to be produced easily and are able to save on space, and also for methods for producing same.

### SUMMARY

Examples of the present disclosure provide a residual current sensor component having the following features: a package formed entirely from a potting material that is exposed to the outside and constitutes an outer boundary of the package; at least one magnetic field sensor arranged in the package; at least two current conductors having sections arranged adjacently in the package; and a magnetic field concentrator that at least partially surrounds the adjacently arranged sections of the at least two current conductors and is configured to concentrate a magnetic field generated by currents flowing through the at least two current conductors onto the magnetic field sensor, wherein the magnetic field concentrator is arranged at least partially in the potting material or is mounted on an outer surface of the package.

Examples of the present disclosure provide a residual current sensor component having the following features:
an insulating plate-shaped carrier;
a magnetic field sensor;
at least two current conductors having adjacently arranged sections; and
a magnetic field concentrator that at least partially surrounds the adjacently arranged sections of the at least two current conductors and is configured to concentrate a magnetic field generated by currents flowing through the at least two current conductors onto the magnetic field sensor,
wherein the insulating plate-shaped carrier carries the magnetic field sensor, the at least two current conductors and the magnetic field concentrator,
wherein a potting material is applied to a main surface of the insulating plate-shaped carrier and covers the magnetic field sensor and at least parts of the magnetic field concentrator, and
wherein parts of the potting material and parts of the carrier are exposed to the outside and constitute an outer boundary of the residual current sensor component.

Examples of the present disclosure provide a current sensor component having the following features:
a package;
at least one magnetic field sensor chip arranged in the package and having a magnetic field sensor;
at least one current conductor having a section arranged in the package; and
a magnetic field concentrator that at least partially surrounds the section of the current conductor arranged in the package and is configured to concentrate a magnetic field generated by a current flowing through the at least one current conductor onto the magnetic field sensor,
wherein part of the magnetic field concentrator is formed on the chip surface of the magnetic field sensor chip.

Examples of the present disclosure provide methods for producing current sensor components and residual current sensor components as described herein.

Examples of the present disclosure thus target an implementation of current sensor components, in particular residual current sensor components, that are able to be produced in a semiconductor package using a typical setup for the manufacture of semiconductor packages. This may in particular be implemented by integrating one, two or four current conductors, which may also be referred to as busbars, into the same package, which has a potting material that is exposed to the outside and constitutes an outer boundary of the package. A magnetic field concentrator may be integrated here into the package or clamped onto the package as a field concentrator clip. In examples, parts of the magnetic field concentrator may be provided on a chip of the magnetic field sensor. Examples of the present disclosure thus enable simple production and space-saving components. Examples also enable measurement of low currents on account of the magnetic field concentrator.

### BRIEF DESCRIPTION OF THE DRAWINGS

Examples of the present disclosure will be described in more detail below with reference to the accompanying drawings. In the figures:

FIGS. 1A-1C show schematic illustrations of a residual current sensor component with lateral detection and an internal magnetic field concentrator according to one example of the present disclosure;

FIGS. 2A-2C show schematic illustrations of a residual current sensor component with vertical detection and an internal magnetic field concentrator according to one example of the present disclosure;

FIGS. 3A and 3B show schematic illustrations of variants of a residual current sensor component with lateral detection and an external magnetic field concentrator according to one example of the present disclosure;

FIGS. 4A and 4B show schematic illustrations of a residual current sensor component with vertical detection and an external magnetic field concentrator according to one example of the present disclosure;

FIGS. 5A and 5B show schematic illustrations of variants of a residual current sensor component with lateral detection and an internal magnetic field concentrator according to a further example of the present disclosure;

FIG. 6 shows a schematic illustration of a residual current sensor component with lateral detection and an internal magnetic field concentrator according to a further example of the present disclosure;

FIG. 7 shows a schematic illustration of a residual current sensor component with vertical detection and an internal magnetic field concentrator according to a further example of the present disclosure;

FIG. 8 shows a schematic illustration of a residual current sensor component with vertical detection and an external magnetic field concentrator according to a further example of the present disclosure;

FIGS. 9A and 9B show schematic illustrations of a residual current sensor component with lateral detection according to one example of the present disclosure, wherein a part of the magnetic field concentrator is formed on a magnetic field sensor chip;

FIGS. 10 and 11 show schematic illustrations of residual current sensor components with lateral detection and different conductor structures of a lead frame according to examples of the present disclosure;

FIGS. 12 and 13 show schematic illustrations of residual current sensor components with vertical detection and different conductor structures of a lead frame according to examples of the present disclosure;

FIGS. 14A-14D show schematic illustrations of a residual current sensor component with lateral detection and an internal magnetic field concentrator according to a further example of the present disclosure in different production phases;

FIGS. 15A-15C show schematic illustrations of a residual current sensor component with vertical detection and an external magnetic field concentrator according to a further example of the present disclosure in different production phases;

FIGS. 16A-16D show schematic illustrations of a residual current sensor component with vertical detection and an internal magnetic field concentrator according to a further example of the present disclosure in different production phases;

FIGS. 17A-17D show schematic illustrations of a residual current sensor component with lateral detection and an internal magnetic field concentrator formed partially on a magnetic field sensor chip, according to a further example of the present disclosure in different production phases;

FIGS. 18A-18D show schematic illustrations of a residual current sensor component with vertical detection and an internal magnetic field concentrator formed partially on a magnetic field sensor chip, according to a further example of the present disclosure in different production phases;

FIGS. 19A and 19B show schematic illustrations of a residual current sensor component with vertical detection and an internal magnetic field concentrator according to a further example of the present disclosure;

FIGS. 20A and 20B show schematic illustrations of a residual current sensor component with vertical detection and an internal magnetic field concentrator according to a further example of the present disclosure;

FIGS. 21A-21D show schematic illustrations of a residual current sensor component with lateral detection according to a further example of the present disclosure in different production phases;

FIGS. 22A-22D show schematic illustrations of a residual current sensor component with vertical detection according to a further example of the present disclosure in different production phases;

FIGS. 23A-23F show schematic illustrations of a residual current sensor component with lateral detection according to a further example of the present disclosure in different production phases;

FIGS. 24A-24F show schematic illustrations of a residual current sensor component with lateral detection according to a further example of the present disclosure in different production phases;

FIGS. 25A and 25B show schematic illustrations of a residual current sensor component with lateral detection and two current conductors according to one example of the present disclosure, for illustrating one example of a lead frame;

FIG. 26 shows a schematic illustration of a residual current sensor component with lateral detection and four current conductors according to one example of the present disclosure, for illustrating one example of a lead frame;

FIGS. 27A and 27B show schematic illustrations of an alternative example of a residual current sensor component;

FIGS. 28A-28C show schematic illustrations for explaining magnetic field concentrators for lateral and vertical detection;

FIGS. 29A and 29B show schematic illustrations of examples of magnetic field concentrators; and

FIGS. 30A-30C show schematic illustrations for explaining vertical and lateral detection.

### DETAILED DESCRIPTION

Below, examples of the present disclosure are described in detail and using the attached drawings. It is pointed out that identical elements or elements having the same functionality are provided with identical or similar reference signs, a repeated description of elements provided with the same or similar reference signs typically being omitted. In particular, identical or similar elements may each be provided with reference signs that have the same number with a different or no lower case letter. Descriptions of elements having identical or similar reference signs are mutually interchangeable. In the following description, a large number of details are described in order to provide a more thorough explanation of examples of the disclosure. However, it is evident to those skilled in the art that other examples may be implemented without these specific details. Features of the various examples described may be combined with one another, unless features of a corresponding combination are mutually exclusive or such a combination is expressly excluded.

The dimensions and measurements mentioned in the following description of the figures are to be understood purely by way of example. They are only used to give a rough insight into the rough orders of magnitude with which the innovative concept described herein takes place. In the figures, elements may be illustrated semi-transparently at least to some extent, so as not to hide elements located beneath or behind them for the purposes of explaining the disclosure.

Examples of the present disclosure target an implementation of current sensor components, in particular residual current sensor components, that are able to be produced in a typical semiconductor package consisting entirely of a cast potting material or consisting merely of an insulating carrier and a potting material applied to the carrier. The potting material may in this case be applied by casting in the usual way using a mold. In this process, molten potting material may be introduced into a mold, flow around the semiconductor chip and a lead frame and fill the entire mold. The potting material may subsequently cure and form the outer package, or form the outer package together with an insulating carrier. The potting material becomes hard when it cures and forms a solid protective covering around the semiconductor chip. The components according to the present disclosure in this case do not have shell-shaped package components assembled in modular form.

In examples, an inherent overcurrent detection mechanism may be connected directly to a driver IC (IC=integrated circuit) for fast response. Examples enable a miniaturized form factor and a low weight. Furthermore, examples enable low costs compared to existing solutions.

Examples of the present disclosure are particularly suitable for wallbox applications, for charging cables or for on-board chargers. In examples, the magnetic field sensor may be implemented by way of Hall technology or xMR technology, for example a Hall chip technology or a vertical xMR chip technology for vertical detection, or an xMR chip technology or a vertical Hall chip technology for lateral detection.

Examples of the present disclosure relate to residual current monitors (RCM), which are dedicated devices configured to continuously monitor and measure current imbalances in a circuit. Examples of the disclosure may in this case be used for residual current circuit breakers (RCCB) or ground fault circuit interrupters (GFCI), which are electrical safety devices that rapidly interrupt an electrical circuit with a leakage current to ground. This serves to protect equipment and reduce the risk of serious injury caused by a sustained electric shock.

The examples of residual current sensor components as described herein may be implemented using “classical semiconductor packages”. Such a package may be understood to be an integrated semiconductor package in which the package is produced using a potting compound. In examples, the package may be a one-piece body produced in one step from a potting material. In examples, the package may consist entirely of a potting material that is exposed to the outside and constitutes an outer boundary of the package. In examples, the potting material may be applied to an insulating plate-shaped carrier, wherein parts of the potting material and parts of the carrier are exposed to the outside and constitute an outer boundary of the residual current sensor component. In such examples, the potting material, together with the insulating plate-shaped carrier, thus constitutes a package.

Examples of the present disclosure thus relate to packaged components that do not have a modular package, wherein a modular package should be understood to mean a package having multiple parts that are assembled to form the package, or in which multiple process steps are necessary to achieve the package. The present disclosure thus relates to package bodies the outer boundary of which is formed at least partially from potting material without the need for one or more prefabricated shells or coverings.

Residual current sensor components according to the present disclosure comprise a magnetic field sensor, at least two current conductors having adjacently arranged sections, and a magnetic field concentrator that at least partially surrounds the adjacently arranged sections of the at least two current conductors and is configured to concentrate a magnetic field generated by currents flowing through the at least two current conductors onto the magnetic field sensor. The magnetic field sensor has a sensor element for detecting a magnetic field. The sensor elements may be magnetoresistive sensor elements, which are also referred to as xMR sensors for short. These include for example TMR (tunnel magnetoresistance) sensors, AMR (anisotropic magnetoresistance) sensors, GMR (giant magnetoresistance) sensors, CMR (colossal magnetoresistance) sensors and the like. In principle, the electrical resistance or conductance of magnetoresistive sensors changes when the sensor is exposed to a magnetic field. In principle, xMR sensors in this case recognize the field strength parallel to a reference direction. This is implemented by way of a resistance-based measurement using different magnetoresistive sensor elements. The sensor elements output an output signal that depends on the magnetic field in the direction in which they are each sensitive. As an alternative, the sensor element may be a Hall sensor.

A magnetic field concentrator is the name given herein to an element suitable for guiding a magnetic field. For this purpose, the magnetic field concentrator may consist of suitable materials with a high magnetic permeability, such as for example a u-metal or ferrite. Other suitable magnetic materials are: MnZn, NiZn, AlSiFe, NiFeMo, NiFe, FeSi, Fe·Si·Nb·Cu·B, CoFe, or materials marketed under the brand name “VITROVAC”. The magnetic field concentrator may serve to guide magnetic fields generated by currents flowing through current conductors to the magnetic field sensor in order to increase sensitivity, on the one hand, and to shield against external magnetic fields, on the other hand. Examples of the present disclosure thereby enable a high signal-to-noise ratio compared to conventional coreless technologies.

According to the present disclosure, the magnetic field concentrator at least partially surrounds one, two, four or more current conductors. The definition whereby the magnetic field concentrator at least partially surrounds the adjacently arranged current conductors should be understood herein to mean that sections of the magnetic field concentrator are arranged on at least three sides of the adjacently arranged sections of the current conductors. In examples, the at least three sides comprise a side of the current conductors that is remote from the magnetic field sensor, and a top and a bottom of the current conductors. In examples, sections of the magnetic field concentrator are arranged on all four sides of the current conductors. The magnetic field concentrator does not have to be continuous, and may have interruptions provided that the interruptions are small enough not to significantly impair the magnetic flux through the magnetic field concentrator, and thus the function thereof.

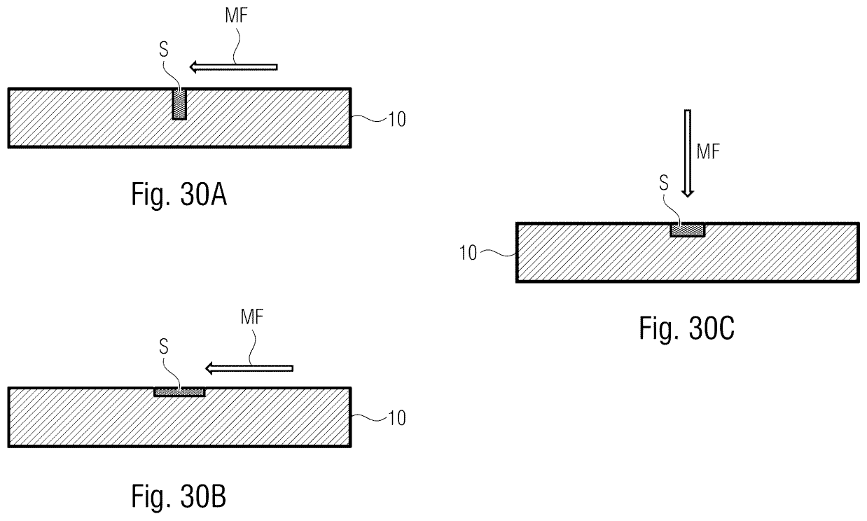

The design of residual current sensor components described herein may differ depending on whether the magnetic field sensor is configured for vertical detection or lateral (horizontal) detection. The expressions “vertical” and “horizontal” (lateral) each refer herein to the chip plane of a magnetic field sensor chip that comprises the magnetic field sensor, unless indicated otherwise. The chip plane is defined by the two main surfaces of the magnetic field sensor chip, that is to say the two opposing largest surfaces thereof. FIGS. 30A-30C each show a magnetic field sensor chip. According to FIG. 30A, a magnetic field sensor S of the magnetic field sensor chip 10 is a vertical Hall element that is configured to detect magnetic fields MF horizontally to the chip plane, that is to say an in-plane field. Such detection is also referred to herein as lateral detection. According to FIG. 30B, the magnetic field sensor chip 10 has an xMR sensor element S that is configured to detect magnetic fields MF horizontally to the chip plane (in-plane fields). According to FIG. 30C, the magnetic field sensor chip 10 has a sensor element S that is configured to detect magnetic fields MF vertically to the chip plane. The vertical detection sensor element S may be implemented by a horizontal (planar, lateral) Hall element or a vertical xMR element.

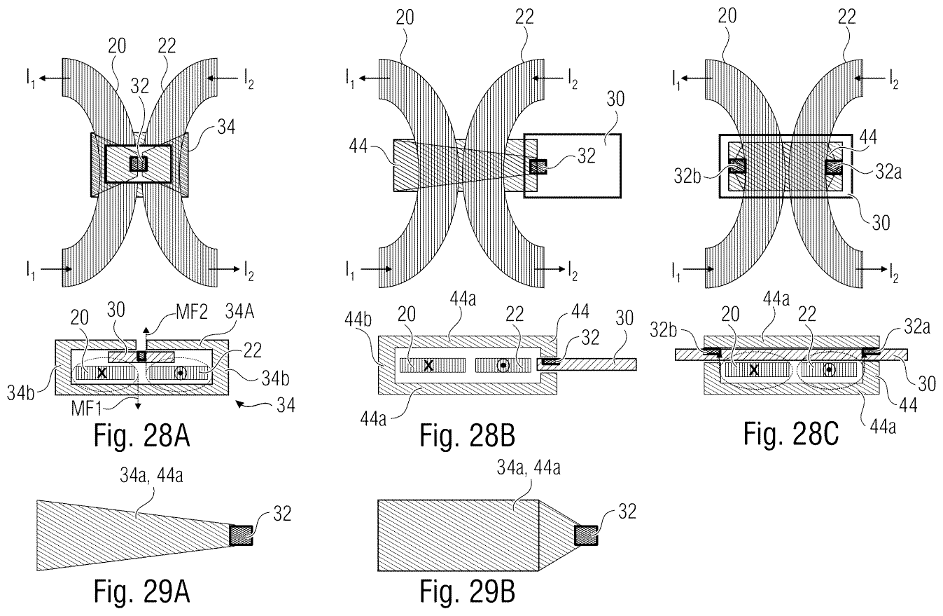

Examples of magnetic field concentrators for supporting lateral or vertical detection of magnetic fields generated by two current conductors are described below with reference to FIGS. 28A-28C. FIG. 28A shows a lateral detection arrangement, whereas FIGS. 28B and 28C show a vertical detection arrangement.

FIG. 28A28C each show a first current conductor 20 and a second current conductor 22. A current I₁ flows through the first current conductor 20 in the direction shown by arrows in FIG. 28A. A current I₂ flows through the current conductor 22 in the direction shown by arrows in FIG. 28A. Currents thus flow in different directions through adjacently arranged sections of the current conductors 20 and 22. In other words, the current paths formed by the two current conductors 20 and 22 are taken up by different phases. The current conductors 20 and 22 may for example represent an outward line and a return line to and from a consumer or a producer, for example a solar installation. If no fault occurs, the two currents should be the same, and no leakage current should occur. In the event of a fault, there will be a difference between the two currents that is able to be detected. For this purpose, provision is made for a magnetic field sensor chip 30 having a magnetic field sensor 32. The magnetic field sensor 32 is intended to detect magnetic fields generated by the currents I₁ and I₂. If these currents are the same, the magnetic field should cancel itself out. However, if a residual current is present, this generates a residual magnetic field that is detected by the magnetic field sensor 32. A magnetic field concentrator 34 is provided in order to concentrate the magnetic field generated by the currents I₁ und I₂ onto the magnetic field sensor 32.

FIGS. 28A-28C each show, in the upper part thereof, a schematic plan view of a corresponding arrangement and, in the lower region thereof, a schematic cross-sectional view. As shown in the respective schematic cross-sectional view, the current flows through the current conductor 20 into the plane of the drawing and the current flows through the current conductor 22 out of the plane of the drawing. As a result, the current through the current conductor 20 generates a magnetic field MF1, and the current through the current conductor 22 generates a magnetic field MF2. The magnetic field concentrator 34 is configured to concentrate these magnetic fields onto the magnetic field sensor 32. The magnetic field sensor 32 thus detects a magnetic difference between the magnetic fields MF1 and MF2. In the example shown in FIG. 28A, the magnetic field sensor 32 is configured to detect a magnetic field in the lateral direction. For this purpose, it is arranged in a region onto which the magnetic field concentrator 34 concentrates the magnetic field. The magnetic field sensor is arranged so as to overlap a region between the at least two current conductors in plan view of the adjacently arranged sections of the two current conductors 20 and 22. The magnetic field sensor 32 is preferably arranged so as to be centered with respect to the at least two current conductors. The magnetic field sensor 32 is preferably arranged between the two current conductors 20 and 22 in plan view. The magnetic field concentrator 34 has first sections 34a that extend away from the magnetic field sensor 32 in opposing directions, second sections 34b that are guided around outer sides of the two current conductors 20 and 22 (generally around the outer of at least two current conductors), and a third section 34c that extends between the second sections 34b of the magnetic field concentrator 34 on the side of the current conductors 20 and 22 that is remote from the first sections 34a. As shown in FIG. 28A, the first sections 34a of the magnetic field concentrator 34 may taper toward the magnetic field sensor 32 in order thereby to concentrate the magnetic field better onto the magnetic field sensor 32. The magnetic field sensor shown in FIG. 28A may be formed by a vertical Hall element or an xMR sensor element.

FIG. 28B shows a vertical detection arrangement. More specifically, the magnetic field sensor 32 is configured to detect a magnetic field in a direction perpendicular to a direction in which the sections of the at least two current conductors 20 and 22 are arranged adjacently. The magnetic field sensor 32 is arranged on an outer side of that section of the current conductor 22 that is arranged next to the corresponding section of the current conductor 20. A magnetic field concentrator 44 is provided in order to concentrate a magnetic field generated by corresponding currents I₁ und I₂ flowing through the current conductors 20 and 22 onto the magnetic field sensor 32. The magnetic field concentrator, starting from the magnetic field sensor 32, has sections 44a that extend transversely over the adjacently arranged sections of the two conductors 20 and 22 and that are arranged on opposing sides of the at least two conductors 20 and 22. The two sections 44a are connected to one another, on the side of the two conductors 20 and 22 that is remote from the magnetic field sensor 32, by a section 44b. Furthermore, in the example shown, the magnetic field concentrator has sections extending from the two sections 44a toward the magnetic field sensor 32 in the vertical direction. The magnetic field sensor 32 is arranged in a gap of the magnetic field concentrator 44. The sections 44a of the magnetic field concentrator 44 taper toward the magnetic field sensor. Although, in the figures relating to the vertical detection, the lower part, in the respective plan view, of the magnetic field concentrator is in each case illustrated as not tapering for illustrative reasons, it is pointed out that this lower section in plan view in reality also tapers or may taper toward the magnetic field sensor 32.

FIG. 28C shows one example of vertical detection in which two magnetic field sensors 32a and 32b are provided. The magnetic field sensors 32a and 32b may be provided in a common magnetic field sensor chip 30 or in separate magnetic field sensor chips. In the example shown in FIG. 28C, the two magnetic field sensors 32a and 32b are provided in a common magnetic field sensor chip 30 that is arranged above the adjacently arranged sections of the current conductors 20 and 22. The magnetic field concentrator 44 has a second gap here in which the second magnetic field sensor 32b is arranged. If the magnetic field sensors 32a and 32b are arranged on separate magnetic field sensor chips, the two magnetic field sensor chips may be provided on both sides of the two current conductors 20 and 22, in the same way as the magnetic field sensor chip shown in FIG. 28B. However, the arrangement shown in FIG. 28C is more space-saving. In the example shown in FIG. 28C, the magnetic field concentrator 44 concentrates the magnetic field onto the two magnetic field sensors 32a and 32b. The magnetic field sensor chip 30 may be configured to generate a difference between the signals generated by the magnetic field sensors 32a and 32b, which may lead to increased accuracy.

There is no need to mention separately that, in this case too, the lower part, in plan view, of the magnetic field concentrator 44 may in turn be formed so as to taper toward the magnetic field sensors 32a and 32b.

FIGS. 29A and 29B show example implementations of magnetic field concentrator sections 34a, 44a that taper toward the magnetic field sensor 32. According to FIG. 29A, the tapering takes place over the entire length of the corresponding section, whereas, according to FIG. 29B, the tapering takes place over only regions of the corresponding section. The magnetic field concentrator and the formation thereof in the proximity of the detection element, that is to say of the magnetic field sensor 32, is configured to support the concentration of the magnetic field onto the detection element of the magnetic field sensor, with the shapes illustrated being purely example.

The above statements with regard to the lateral and vertical detection, along with the above statements with regard to the arrangement of the current conductors, the magnetic field sensor, the magnetic field sensor chip and the magnetic field concentrator, may be carried over to all of the examples explained below, provided they do not contradict the examples, and will not repeated in detail each time.

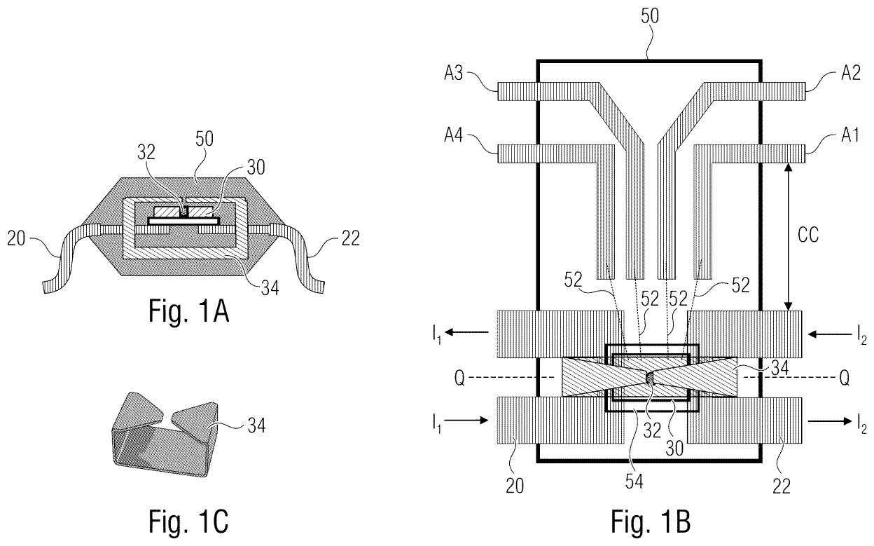

With reference to FIGS. 1A-1C, a description will now be given of a residual current sensor component according to one example of the present disclosure, in which a package 50 consists entirely of a potting material that is exposed to the outside and constitutes an outer boundary of the package. FIG. 1A shows a schematic cross-sectional view along Q-Q in FIG. 1B, whereas FIG. 1B shows a schematic plan view of the component. A magnetic field sensor chip 30 having a magnetic field sensor 32 is arranged in the manner described above with respect to a magnetic field concentrator 34 in the package 50. The residual current sensor component furthermore has a lead frame, wherein current conductors 20 and 22 are formed as part of the lead frame. The lead frame also has signal connections and power supply connections A1 to A4. In the figures, parts of the lead frame are generally illustrated by vertical hatching.

There is no need for any further explanation that the magnetic field sensor chip 30, which constitutes a semiconductor chip, has a suitable circuit structure alongside the magnetic field sensor 32 in order to generate sensor output signals. The connections A1 to A4 may be configured to output appropriate output signals, possibly based on appropriate control signals, and to supply power to the magnetic field sensor chip 30. There should be a sufficient clearance CC (creepage clearance) between the connections A1 to A4 and the current conductors 20 and 22 to minimize the risk of flashover or a leakage current.

As shown in FIG. 1B, respective connections of the magnetic field sensor chip 30 may be connected to the connections A1 to A4 via bonding wires 52. FIG. 1B furthermore shows an insulating structure in the form of an insulation layer 54, which may be provided between the magnetic field sensor chip 30 and the lead frame, more precisely the current conductors 20 and 22 thereof. FIG. 1A in this case shows the finished component, wherein it may be seen that the package 50 is formed from the potting material, from which the connections of the lead frame, for example the connections of the current conductors 20 and 22, protrude. Furthermore, as shown in FIG. 1B, the connections A1 to A4 of the lead frame also protrude from the package 50.

As shown in FIG. 1B, the current conductors 20 and 22 are U-shaped, wherein each of the current conductors 20 and 22 has two parallel sections forming the limbs of the U-shaped conductor, and a connecting section connecting the two limbs. The connecting sections of the U-shaped conductors 20 and 22 form the adjacently arranged sections of the at least two current conductors. FIG. 1C shows an example illustration of the magnetic field concentrator 34. The magnetic field concentrator is arranged so as to surround the connecting section of the U-shaped current conductors 20 and 22. In this example, the magnetic field concentrator is arranged entirely in the potting material.

The expression “lead frame” is used herein with its meaning familiar to those skilled in the art, it being understood to mean a metal frame, which may for example be made of copper or a copper alloy, as a carrier for integrated circuits. The lead frame may be covered with a coating of silver, nickel or gold in order to improve conductivity and prevent corrosion. The lead frame may serve as a carrier for a semiconductor chip, for example the magnetic field sensor chip 30, and is able to provide it with mechanical stability. It is able to hold and protect the chip in a fixed position both during the production process and during use, and its main task is to establish electrical connections between internal circuits of the integrated circuit and external connections of the package. During production, the magnetic field sensor chip is placed on the lead frame and connections of the magnetic field sensor chip are connected to corresponding connections of the lead frame by wire bonding or flip-chip methods. Encapsulation into the potting material is then carried out to complete the component, thereby forming a robust component for use in electronic devices. In examples, the potting material may consist of an epoxy resin to which fillers and additives may be added. Epoxy resin, due to its good electrical insulation, good thermal resistance and moisture resistance, is suitable as a potting material for providing mechanical protection against mechanical damage such as vibrations or impact loads. Epoxy resin as potting material is also able to be processed easily in the liquid state and then cures to form a solid, protective package. In other examples, the potting material may consist of silicone, polyurethane, polyamide, acrylic, thermoplastic potting compounds or liquid-crystal polymer.

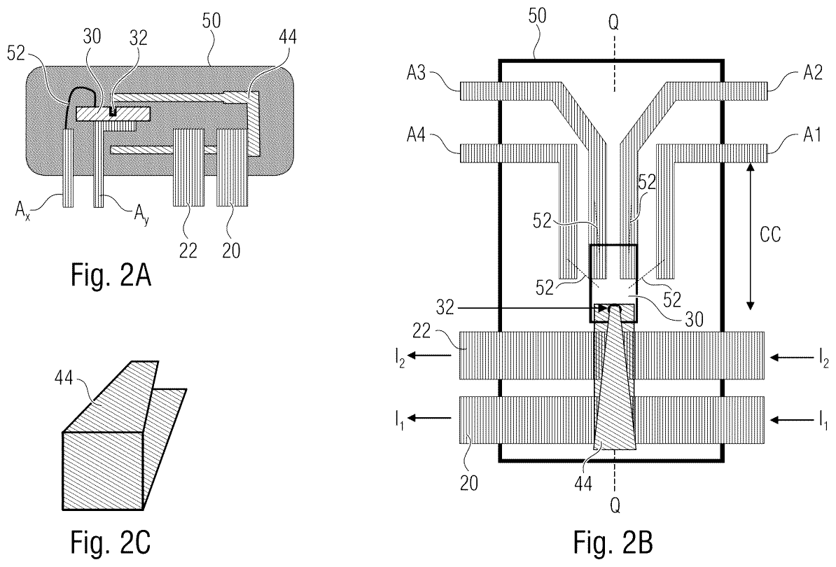

FIGS. 2A-2C show schematic illustrations of a residual current sensor component with vertical detection, in which the package is likewise formed entirely from a potting material that is exposed to the outside and constitutes an outer boundary of the package. FIG. 2A in this case illustrates a schematic cross-sectional view along Q-Q in FIG. 2B, whereas FIG. 2B illustrates a schematic plan view and FIG. 2C illustrates a perspective view of the magnetic field concentrator. As has been described above with reference to FIGS. 1A-1C, two current conductors 20 and 22 and connections A1 to A4 are again formed as parts of a lead frame. The two current conductors 20 and 22 are formed here as straight conductors. A magnetic field concentrator 44 is again provided so as to at least partially surround the two current conductors 20 and 22, for example as has been described above with reference to FIG. 28B. However, in this example, the sections of the magnetic field concentrator 44 that extend in the vertical direction toward the magnetic field sensor 32 are not provided. As shown in FIG. 2A, the magnetic field sensor chip 30 may be arranged directly on a part of the lead frame, wherein a connection surface of the magnetic field sensor chip 30 may also be connected directly to the corresponding part of the lead frame via a flip-chip connection rather than by bonding wires 52. Also in the example shown in FIG. 2B, all components, with the exception of the protruding connections of the lead frame, are arranged in the package formed entirely from a potting material.

The example shown in FIG. 2B is advantageous in that those sections of the at least two current conductors that are arranged in the package run straight through the package.

As has been described, in examples, the magnetic field concentrator is arranged entirely in the potting material. In other examples, at least parts of the magnetic field concentrator are mounted on an outer surface of the package. In examples, the magnetic field concentrator is clamped onto the package as a chip.

It is pointed out at this juncture that the parts of the lead frame concerning the connections A1 to A4 are indicated purely schematically in the schematic cross-sectional illustration in FIG. 2A and are designated Ax and Ay, wherein, according to the present disclosure, the exact design of the connection lines A1 to A4 is irrelevant. The same applies to the corresponding cross-sectional illustrations of the other special examples described herein.

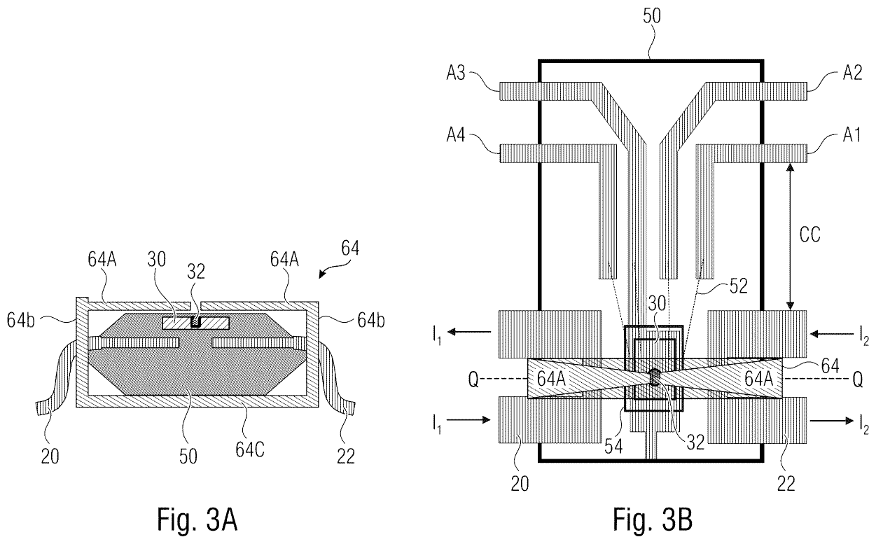

FIG. 3A shows a schematic cross-sectional illustration along Q-Q in FIG. 3B, and FIG. 3B shows a schematic plan view of one example of a residual current sensor component having a magnetic field concentrator 64 mounted on an outer surface of the package 50. By way of example, the magnetic field concentrator 64 may be clamped onto the outer surface of the package 50 as a clip. In this case, first sections 64a of the magnetic field concentrator 64 extend from the magnetic field sensor 32 to the outer edges of the package 50, and second sections 64b extend around the outer edges of the package 50. A third section 64c of the magnetic field concentrator 64 extends between the second sections 64b on the side of the current conductors 20 and 22 that is remote from the first sections 64a. As may be seen in FIG. 3B, the magnetic field sensor chip is positioned on a corresponding section of the lead frame in the form of a chip pad, wherein an insulator 54 may be arranged between them. In the examples described herein, the magnetic field sensor chip may be mounted in each case on a chip pad of a lead frame in the usual form. Connections of the magnetic field sensor chip 30 may in turn be connected to the connections A1 to A4 of the lead frame via bonding wires. It is also pointed out that the first sections 64a may lie on the upper surface of the package 50 and are not spaced therefrom, as shown in FIG. 3A. For the rest, reference may be made to the above statements with regard to FIGS. 1A and 1B. It is pointed out in this regard that, depending on the circumstances, the magnetic field sensor chip may be arranged longitudinally, as shown in FIG. 1B, or transversely, as shown in FIG. 3B, with respect to the current conductors 20 and 22, wherein FIG. 3A shows the magnetic field sensor chip arranged longitudinally on a purely schematic basis, whereas FIG. 3B shows the magnetic field sensor chip 30 arranged transversely. In the example shown in FIGS. 3A and 3B, the magnetic field sensor chip 32 is configured for lateral detection.

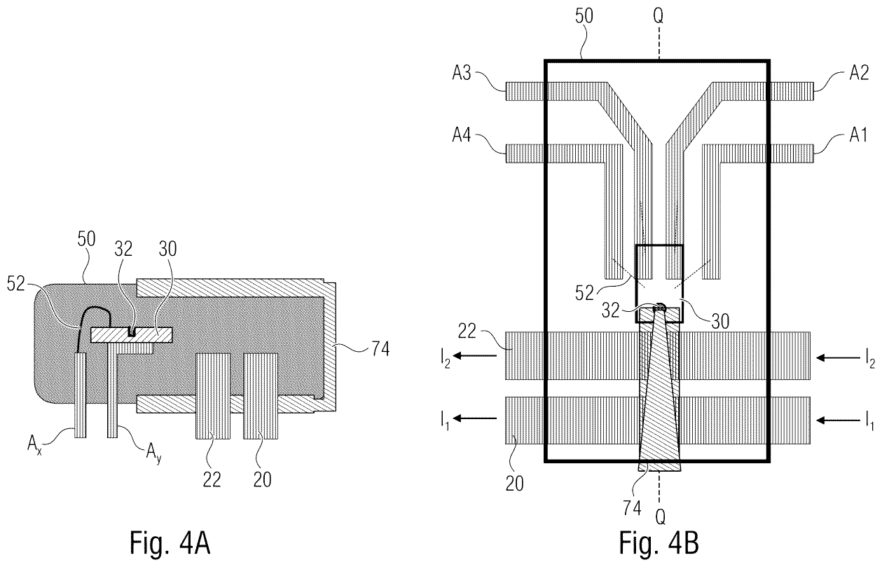

FIG. 4A shows a schematic cross-sectional view along Q-Q in FIG. 4B, and FIG. 4B shows a schematic plan view of a residual current sensor component with vertical detection, in which a magnetic field concentrator 74 is arranged on an outer surface of the package 50, which is formed entirely from a potting material. By way of example, the magnetic field concentrator 74 may be clamped onto an outer surface of the potting material of the package 50 as a clip. The example shown in FIGS. 4A and 4B thus differs from the example shown in FIG. 2A-2C through the arrangement of the magnetic field concentrator 74, wherein, for the rest, reference may be made to the above statements. The example shown in FIGS. 4A and 4B is advantageous in that the conductors 20 and 22 are able to run completely straight in the package 50 and, moreover, the magnetic field concentrator 74 is able to be clamped easily, for example, onto the potting material of the package 50. Moreover, the magnetic field concentrator 74 may have a U-shape, as shown in FIG. 2C, wherein only the limbs of the U-shape and the section connecting the limbs are each adapted in terms of length so as to fit around the potting material, wherein the limbs reach as far as the magnetic field sensor 32 in the direction transverse to the adjacent current conductors 20 and 22.

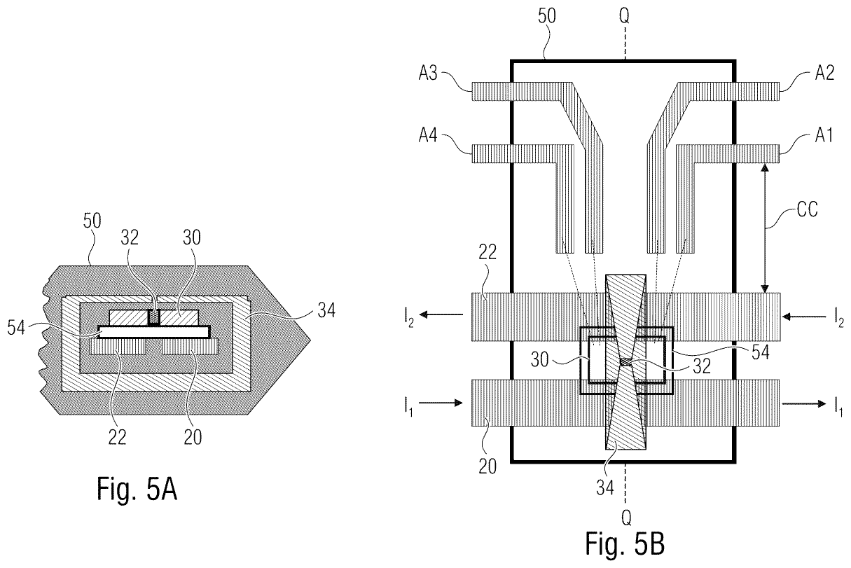

FIG. 5A shows a schematic cross-sectional illustration (along Q-Q in FIG. 5B) of a part of a residual current sensor component with lateral detection, and FIG. 5B shows a schematic plan view of a corresponding residual current sensor component. In this example, the magnetic field concentrator 34 is arranged entirely in the package 50, which consists entirely of a potting material. The semiconductor chip 30 is arranged, by way of an insulator 54, on parts of the lead frame that form the current conductors 20 and 22. In the variant shown in FIG. 5A, the clearance between the two current conductors 20 and 22 is slightly smaller than in the variant shown in FIG. 5B. As shown in FIG. 5B, in this example, the two current conductors 20 and 22 run completely straight through the package 50. The magnetic field sensor 32 is arranged between the current conductors 20 and 22, and the magnetic field concentrator 34 extends around the two current conductors 20 and 22, as has been described for example above with reference to FIG. 1B and is shown in FIG. 5B. In this example, the chip may first be encapsulated in a potting material together with the lead frame in order to form an inner package section around which the magnetic field concentrator 34 is provided. Encapsulation into a further potting material 50 is then carried out to complete the package, wherein this potting material is exposed to the outside and constitutes an outer boundary of the package. It is pointed out at this juncture that the cross-sectional view of FIG. 5A is truncated and does not show the part with the connections A1 to A4.

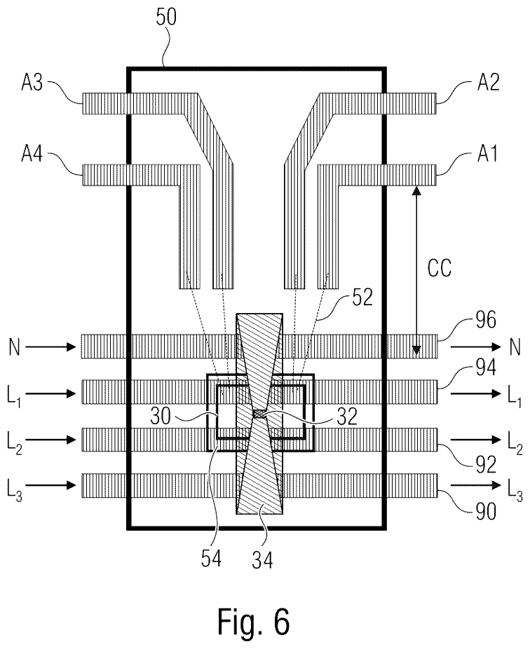

In examples of the present disclosure, sections of two current conductors are arranged adjacently in the package. In other examples, the current conductors comprise four current conductors, wherein the magnetic field concentrator at least partially surrounds adjacently arranged sections of the four current conductors. FIG. 6 shows a schematic plan view of a residual current sensor component with lateral detection, in which sections of four conductors are arranged adjacently in the package 50. As shown in FIG. 6, four conductors 90, 92, 94 and 96 extend completely straight through the package 50, these conductors being part of the lead frame. Currents of different phases L₃, L₂, L₁ and N flow through the conductors 90 to 96. The magnetic field sensor 32 is arranged so as to detect a magnetic field generated by these currents. This magnetic field should cancel itself out if no fault is present. In the event of a fault, a residual current generates a residual magnetic field that is detected by the magnetic field sensor 32. The magnetic field concentrator 34 is again provided for this purpose. The magnetic field sensor 32 is provided in this case between the two middle conductors 92 and 94, and the magnetic field concentrator 34 extends around all four current conductors 90 to 96. The example shown in FIG. 6 differs from the example shown in FIGS. 5A and 5B in that, instead of the two current conductors 20 and 22, four current conductors 90 to 96 are provided. For the rest, reference may be made to the above statements.

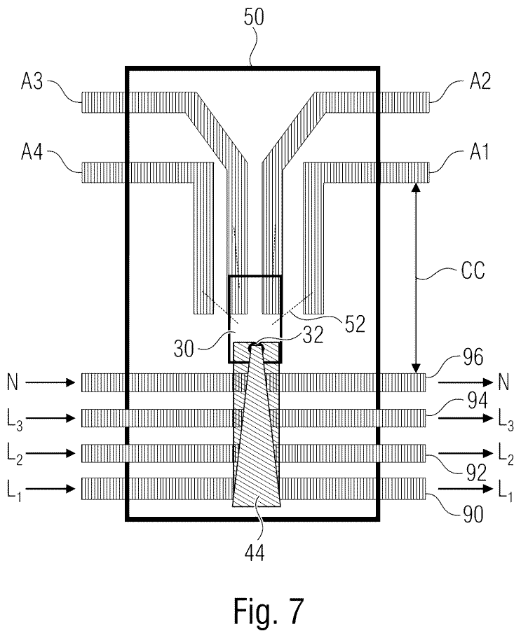

FIG. 7 shows a schematic plan view of a residual current sensor component according to the present disclosure, in which four current conductors 90, 92, 94 and 96 are provided in the package 50. For the rest, the component shown in FIG. 7 corresponds to the component described above with reference to FIG. 2A-2C, and so, for the rest, reference is again made to the above statements. The magnetic field sensor 32 is configured for vertical detection in the example shown in FIG. 7, and the magnetic field concentrator 44 extends around adjacently arranged sections of all four current conductors 90 to 96. The magnetic field sensor 32 is arranged on an outer side of the outer current conductor 96, as shown in FIG. 7.

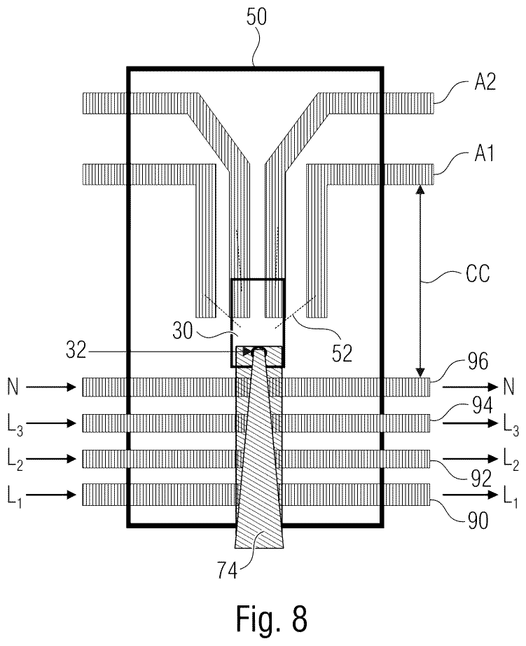

FIG. 8 shows a schematic plan view of one example of a residual current sensor component in which a magnetic field concentrator 74 is provided on an outer surface of the package, which consists entirely of a potting material. The example shown in FIG. 8 corresponds to the example shown in FIG. 4B, with the exception that, instead of the two current conductors 20 and 22, four current conductors 90 to 96, as have been described above by way of example with reference to FIGS. 6B and 7, are provided. The magnetic field concentrator 74 is again provided so as to enclose all four current conductors 90 to 96, and the magnetic field sensor 32, as has been described above with reference to FIG. 7, is arranged on an outer side of the current conductor 96. This example is advantageous in that it is possible to detect a residual current with respect to four current conductors 90 to 96 through which different phases flow, wherein the magnetic field concentrator may easily be mounted on an outer surface of the potting material, for example in the form of a clip. For the rest, reference is again made to the above statements.

In examples of the present disclosure, sections of the magnetic field concentrator are formed on a chip surface of the magnetic field sensor. The definition whereby sections of the magnetic field concentrator are formed on a chip surface of the magnetic field sensor may be understood herein to mean that these sections are produced on the chip surface of the magnetic field sensor before the magnetic field sensor chip is positioned relative to other parts of the magnetic field concentrator in order to produce the complete magnetic field concentrator.

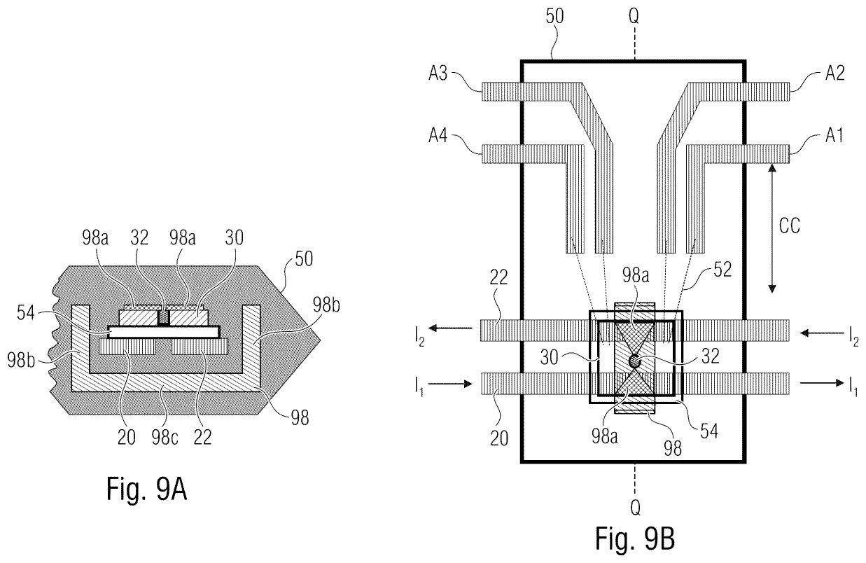

One such example of a magnetic field sensor with lateral detection is shown in FIGS. 9A and 9B, wherein FIG. 9A shows a schematic cross-sectional view of the lower part of FIG. 9B along Q-Q, and FIG. 9B shows a schematic plan view. The magnetic field concentrator 98 is arranged entirely in the package 50, which is formed entirely from a potting material. An insulating component 54 is arranged between two current conductors 20, 22 and the magnetic field sensor chip 30. The magnetic field sensor chip 30 is arranged such that the magnetic field sensor 32 is arranged between the current conductors 20, 22 in plan view. Those parts of the current conductors 20 and 22 that are arranged in the package 50 are straight. The magnetic field concentrator 98 has first sections 98a that are formed on an upper surface of the magnetic field sensor chip 30, and second sections 98b that extend away from the magnetic field sensor 32 in opposing directions and that are guided externally around the two current conductors 20 and 22, and a third section 98c that extends between the second sections 98b of the magnetic field concentrator 98 on the side of the current conductors 20, 22 that is remote from the first sections 98a. The example shown in FIGS. 9A and 9B differs from the example shown in FIGS. 5A and 5B in that the magnetic field concentrator 98 is not formed in one piece, like the magnetic field concentrator 34, but rather that parts of the magnetic field concentrator 98, namely the first sections 98a, are formed on a surface of the magnetic field sensor chip 30.

In examples, the magnetic field concentrator is formed such that a clearance between parts of the magnetic field concentrator that are arranged on the surface of the magnetic field sensor chip 30 and other sections is as small as possible. For this purpose, laterally running sections of the magnetic field concentrator 64 could be provided at the upper end of the second sections 98b and extend toward the outer ends of the first sections 98a. It is also pointed out at this juncture that the magnetic field concentrators disclosed herein do not each have to completely surround the current conductors, as long as it is possible to achieve the purpose of concentrating the magnetic field onto the magnetic field sensor. For instance, gaps could be provided between sections of the respective magnetic field concentrator, the gaps however having a size small enough to not significantly impair the magnetic flux.

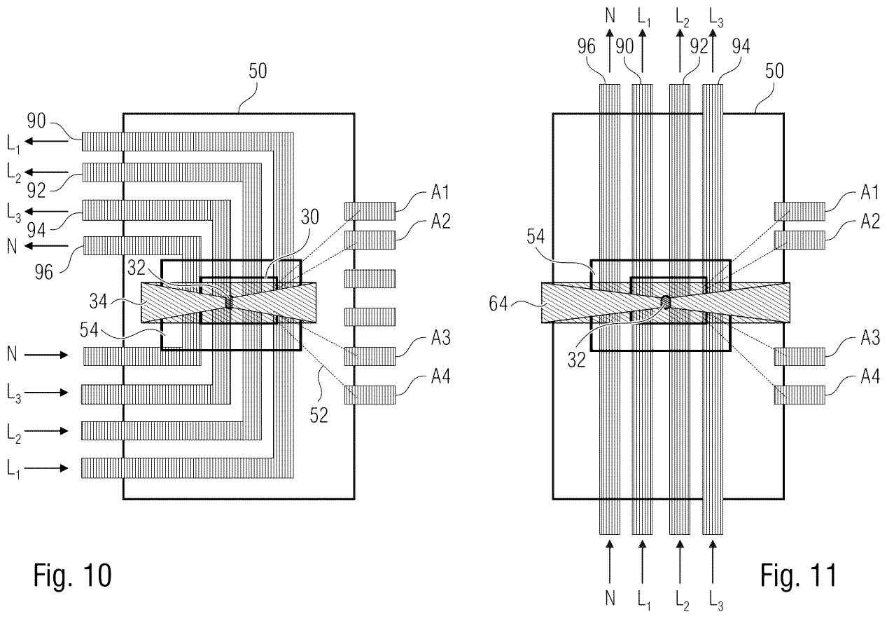

FIGS. 10 and 11 show schematic plan views of examples of residual current sensor components according to the present disclosure, and in particular example wiring options. In the examples shown in FIGS. 10 and 11, the magnetic field sensor 32 is configured to detect a lateral magnetic field. In the example shown in FIG. 10, four current conductors 90 to 96 are U-shaped, wherein limbs of the U-shaped current conductors form outer connections that are arranged on a longitudinal side of the package 50. Signal/power supply connections A1 to A4 are arranged on the opposite longitudinal side of the package. According to FIG. 11, four straight current conductors 90 to 96 are arranged in the package, wherein connections of the four straight current conductors are arranged on opposing transverse sides (short sides) of the package, whereas four signal/power supply connections A1 to A4 are arranged on a longitudinal side of the package 50. In the example shown in FIG. 10, the magnetic field concentrator 34 is arranged entirely in the package 50, whereas the magnetic field concentrator 64 in the example shown in FIG. 11 is provided on the outer surface of the package 50.

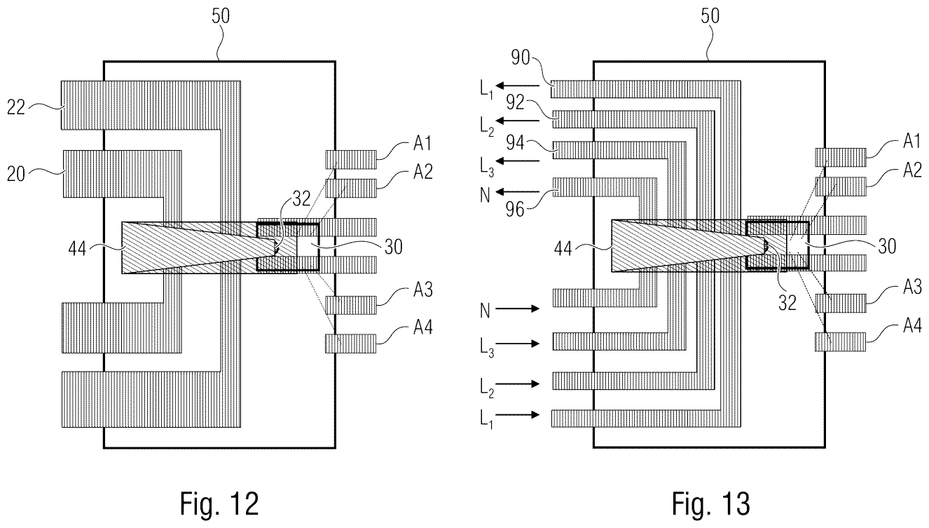

FIGS. 12 and 13 show schematic plan views of examples of residual current sensor components with vertical detection, and in particular examples of different wiring options. According to FIG. 12, provision is made for two U-shaped current conductors 20 and 22 around which the magnetic field concentrator 44 arranged in the package 50 extends in order to concentrate the magnetic field onto the magnetic field sensor 32. Connections of the current conductors 20 and 22 extend from a longitudinal side of the package 50. Signal/power supply connections A1 to A4 extend from the opposite longitudinal side of the package 50. According to FIG. 13, provision is made for four U-shaped current conductors 90 to 96 the connections of which extend from a longitudinal side of the package 50. The magnetic field concentrator 44 surrounds the four current conductors 90 to 96 on three sides thereof in order to concentrate the magnetic field onto the magnetic field sensor 32. Signal/power supply connections A1, A2, A3 and A4 extend from an opposite longitudinal side of the package 50.

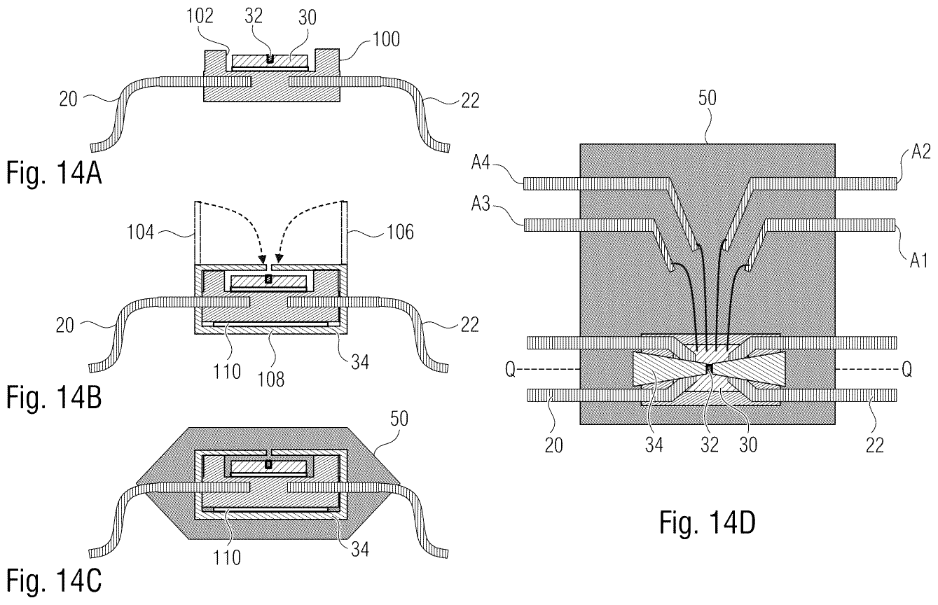

In examples, the residual current sensor component has an insulating component in which the adjacently arranged sections of the at least two current conductors are arranged, wherein the magnetic field concentrator is formed on the outer surface of the insulating component, and wherein the potting material of the package covers the magnetic field sensor and at least parts of the magnetic field concentrator and of the insulating component. One such example will be explained in more detail below with reference to FIG. 14A-14D, alongside a method for producing same.

FIG. 14A shows an intermediate product comprising an insulating component 100. The insulating component 100 has a recess 102 in a main surface thereof, the upper surface thereof in FIG. 14A, with the magnetic field sensor chip 30 having the magnetic field sensor 32 being arranged in the recess. An adhesive layer may be arranged between the insulating component and the magnetic field sensor chip 30. The intermediate product furthermore comprises a lead frame having two current conductors 20 and 22. FIG. 14A thus illustrates an intermediate product comprising an insulating component 100, the magnetic field sensor 32 and at least two current conductors 20, 22.

A preform of a magnetic field concentrator is then provided. The preform of the magnetic field concentrator is U-shaped with two limbs 104, 106, which are illustrated in partially dashed form in FIG. 14B, and a bottom 108 that connects the two limbs 104, 106. The preform of the magnetic field concentrator is mounted on the intermediate product by inserting the insulating component 100 into the interior of the U-shaped preform of the magnetic field concentrator. In this case, an adhesive layer 110 may be provided between the insulating component 100 and the preform of the magnetic field concentrator. The upper ends of the limbs 104, 106 are then bent inward so as to end up lying on the top of the insulating component. The ends of the limbs 104, 106 are thereby bent toward the magnetic field concentrator in order to produce a magnetic field concentrator 34, as has been described above for example with reference to FIG. 28A.

A potting process is then carried out to form the package 50. In this process, potting material is applied so as to cover at least the magnetic field concentrator 34 and form the package 50. As shown in FIG. 14C, the package is formed entirely from the potting material, which is exposed to the outside and constitutes an outer boundary of the package. FIG. 14C shows a schematic cross-sectional illustration of the finished product along Q-Q in FIG. 14D. FIG. 14D shows a schematic plan view of the product. The component thereby produced may correspond essentially to the component shown in FIG. 1A-1C, wherein reference may be made to the above statements with regard to further explanations. As shown in FIG. 14D, the shape of the current conductors 20, 22 and of the connections A1 to A4 differs slightly from the shape shown in FIG. 1A-1C.

In examples of the present disclosure, the insulating component 100 may be a pre-cast component made of plastic. In other examples, the insulating component may be formed from another suitable insulating material, such as for example ceramic or epoxy resin.

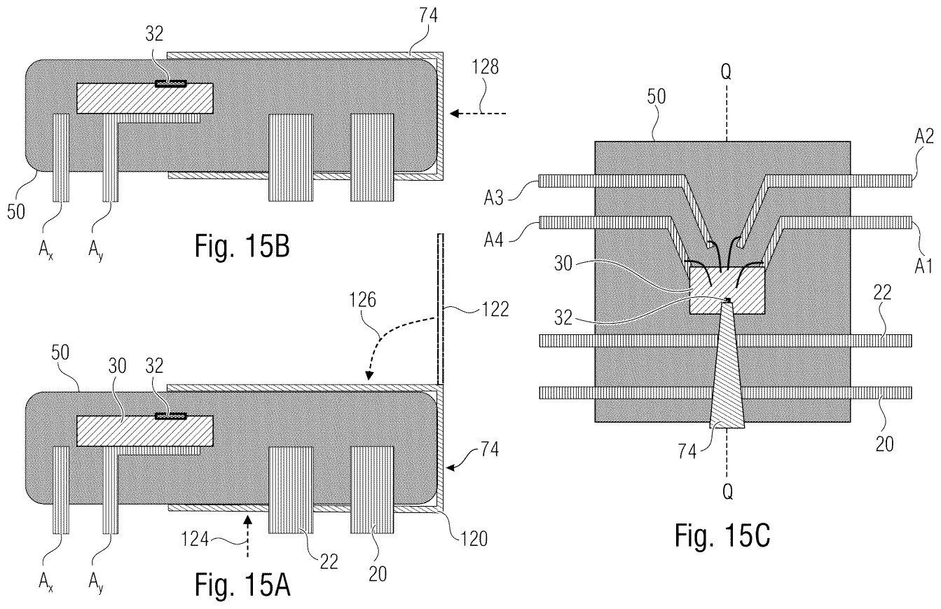

FIGS. 15A-15C show schematic illustrations for explaining a method for producing one example of a residual current sensor component with vertical detection, in which the magnetic field concentrator is provided on an outer surface of the package. FIGS. 15A and 15B in this case illustrate schematic cross-sectional views along Q-Q in FIG. 15C. The method may be used for example to produce a residual current sensor component as shown in FIGS. 4A and 4B. As shown in FIG. 15A, a package in which the magnetic field sensor 32 and the at least two current conductors 20, 22 are packaged is first produced or provided. The package 50 consists entirely of potting material. The magnetic field concentrator is applied to the outer surface of the potting material 50. For this purpose, a preform of the magnetic field concentrator, which is illustrated partially in dashed lines in FIG. 15A, is provided. The preform forms a right angle with a lateral limb 120 and a vertical limb 122. The lateral limb is mounted on the bottom of the package 50, as indicated by an arrow 124 in FIG. 15A. An adhesive layer may be provided between the lateral limb 120 and the package 50. The lower part of the vertical limb 122 rests against the outside of the package 50, wherein an adhesive layer may likewise be provided between them. The upper part of the vertical limb 122 is then bent inward, as indicated by an arrow 126 in FIG. 15A. This upper part of the vertical limb 122 thereby ends up lying on the upper surface of the package 50, wherein an adhesive layer may again be arranged between them. The magnetic field concentrator 74, as has been described above by way of example with reference to FIG. 4A, is thereby produced. A plan view of the resulting component is shown in FIG. 15C, wherein this may correspond essentially to the components described in FIGS. 4A and 4B.

As an alternative to the procedure described above, the magnetic field concentrator 74 may be clamped onto the outer surface of the package 50 as a clip. FIG. 15B shows such a procedure in which the magnetic field concentrator 74 is provided as a clip and is pushed onto the package from one side, the right-hand side in FIG. 15B, and clamped thereon, as shown by an arrow 128 in FIG. 15B. This also yields a component as shown in FIG. 15C. The clip is in this case U-shaped, wherein, in the initial state, the distance between the two ends of the limbs may be slightly smaller than the thickness of the package 50 in the vertical direction, such that these ends are pulled apart from one another for pushing onto the package 50, and, after they are released, clamp the magnetic field concentrator 74 onto the package 50.

Methods for applying a magnetic field concentrator to a package having a magnetic field sensor for vertical detection have been described with reference to FIG. 15A-15C. Appropriate methods may also be used to apply a magnetic field concentrator to a package having a magnetic field sensor for lateral detection. For this purpose, a preform of a magnetic field concentrator, as has been described above with reference to FIG. 14A-14D and that is adapted accordingly for a package, may be pushed onto the package from below, wherein the upper ends of the limbs of the U-shaped preform are then bent inward so as to produce a magnetic field concentrator 64, as shown for example in FIG. 3A of the present application. In such examples, an adhesive may be provided in each case between regions of the magnetic field concentrator and the package.

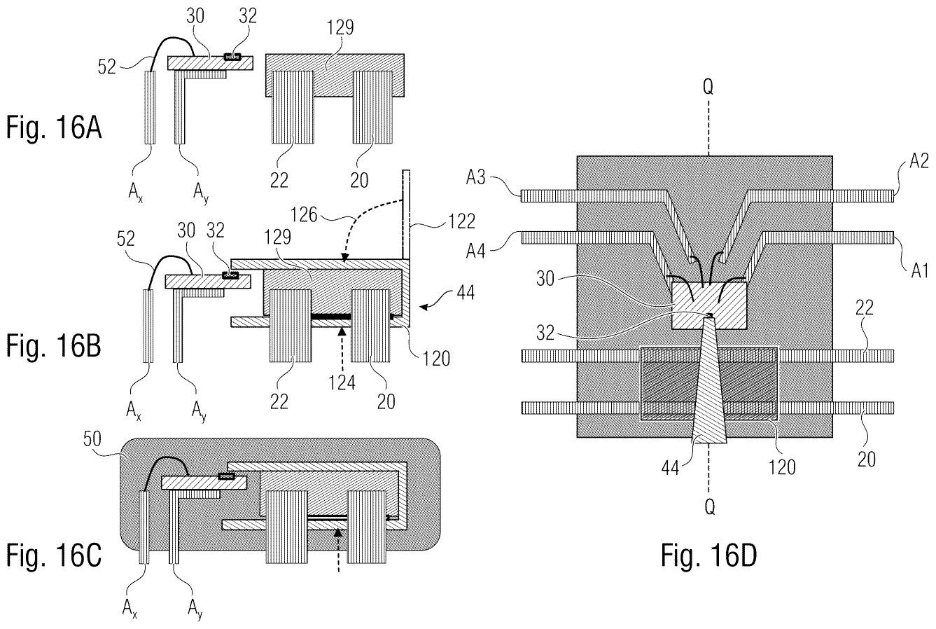

A further example of a residual current sensor component with vertical detection and a method for producing same are described with reference to FIG. 16A-16D. FIGS. 16A and 16B in this case each show intermediate products during production, FIG. 16C shows a schematic cross-sectional illustration of a part of the residual current sensor component along Q-Q in FIG. 16D, and FIG. 16D shows a schematic plan view thereof.

First, as shown in FIG. 16A, an intermediate product is provided, the intermediate product comprising the lead frame with signal/power supply connections Ax, Ay and two current conductors 22 and 20. As may be seen in FIG. 16A, the magnetic field sensor chip 30 having the magnetic field sensor 32 is mounted on a part of the lead frame. The current conductors 20 and 22 are provided on an insulating component 129. The elements shown in FIG. 16A may be connected to one another via parts of the lead frame (not shown). By way of example, these parts may be removed from the potting material in the usual way after the package has been produced, this being able to apply to all of the examples described herein. Starting from the intermediate product shown in FIG. 16A, a preform of a magnetic field concentrator, which forms a right angle with a lateral limb 120 and a vertical limb 122, which is illustrated in partially dashed form in FIG. 16B, is produced. The lateral limb 120 is mounted on the bottom of the insulating component 129. The lower part of the vertical limb 122 rests against the outside of the insulating component 129. The upper part of the vertical limb 122 is then bent around the edge of the insulating component 129, as shown by an arrow 126 in FIG. 16B. A U-shaped magnetic field concentrator 44 is thereby produced, as has been described above by way of example in FIGS. 2A and 2B. A potting material is then applied in order to produce the package 50, which is formed entirely from the potting material. The product shown in FIGS. 16C and 16D may correspond essentially to the component shown in FIG. 2B, and so reference may be made to the above statements with regard to FIG. 2A-2C with regard to further explanations.

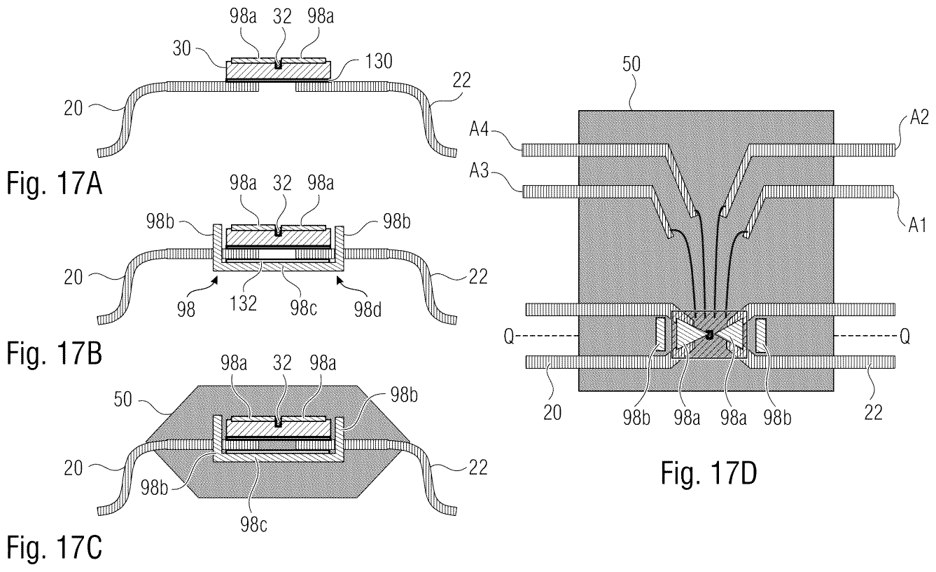

One example of a residual current sensor component with lateral detection, in which a part of the magnetic field concentrator is formed on the magnetic field sensor chip, is described below with reference to FIGS. 17A-17D. FIG. 17A shows a schematic cross-sectional view of a preform comprising the magnetic field sensor chip 30 having the magnetic field sensor 32 and a lead frame having the current conductors 20 and 22. The magnetic field sensor chip 30 is mounted on the lead frame, for example by way of an insulating adhesive layer 130. First sections 98a of a magnetic field concentrator are formed on the upper surface of the magnetic field sensor chip 30. A U-shaped part 98d of the magnetic field concentrator is pushed onto this preform from that side of the lead frame that is remote from the magnetic field sensor chip 30. Limbs of the U-shaped part 98d constitute second sections 98b of the magnetic field concentrator, and a bottom of the U-shaped part 98d constitutes a third section 98c of the magnetic field concentrator. This results in a magnetic field concentrator as has been described by way of example above with reference to FIG. 9A, parts of which, namely the first sections 98a, are formed on the upper surface of the magnetic field sensor chip 30. An adhesive layer 132 may again be provided between the third section 98c and the lead frame. The upper ends of the second sections 98b again extend as close as possible to the outer ends of the first sections 98a so as to keep a gap between these sections of the magnetic field concentrator as small as possible. A potting material is then applied so as to produce the outer package of the residual current sensor component, the outer package being formed entirely from the potting material, as shown in FIG. 17C. The example described with respect to FIGS. 17A-17D differs from the example shown in FIGS. 9A and 9B in that the current conductors 20 and 22 are U-shaped, and so the arrangement of the magnetic field sensor chip 30 and the magnetic field concentrator 98 is rotated by 90 degrees. For the rest, reference may in this case too be made to the above description.

In the examples described, in which parts of the magnetic field concentrator are formed on the surface of the magnetic field sensor chip, these may also be connected to the other parts of the magnetic field concentrator, either through direct contact or by connecting parts that are provided in addition. The magnetic flux between these parts may thereby be improved.

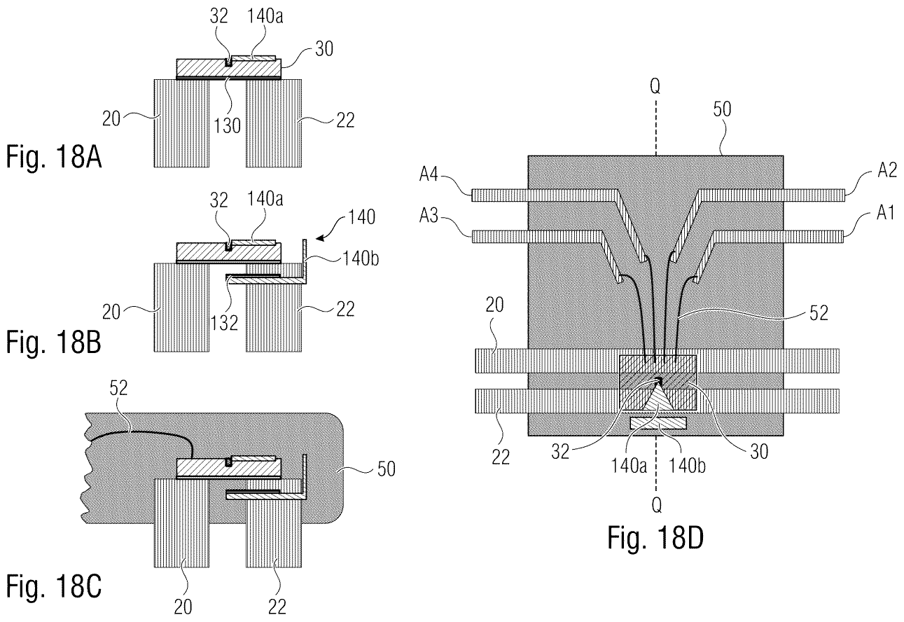

One example of a residual current sensor component with vertical detection, together with method steps for producing same, in which parts of the magnetic field concentrator are formed on the magnetic field sensor chip, are described below with reference to FIGS. 18A-18D.

FIG. 18A shows a schematic cross-sectional illustration of a preform comprising the magnetic field sensor chip 30 having the magnetic field sensor 32 and the lead frame having the conductors 20 and 22. The magnetic field sensor chip 30 is for example mounted on the lead frame by way of an adhesive layer 130. A part 140a of a magnetic field concentrator 140 is formed on the upper surface of the magnetic field sensor chip 30. As shown in FIG. 18B, an L-shaped part 140b of the magnetic field concentrator 140 is pushed onto the lead frame from that side of the lead frame that is remote from the magnetic field sensor chip 30 and for example mounted on the lead frame by way of an adhesive layer 132. The upper end of the short limb of the L-shaped part 140b is thereby positioned in the proximity of the outer end of the part 140a so as to produce a magnetic field concentrator 140, the part 140a of which extends from the magnetic field sensor 32 to the upper end of the short limb of the part 140b, wherein the long limb of the L-shaped part 140b extends to the magnetic field sensor 32 on the opposite side. A vertical magnetic field is thereby able to be concentrated at the location of the magnetic field sensor 32. Again, a gap between the outer end of the part 140a and the upper end of the short limb of the part 140b should be as small as possible in order not to excessively impair the magnetic flux. For this purpose, a vertical section extending toward the magnetic field sensor 32 could be provided at the end of the long limb of the L-shaped part.

Again, as shown in FIG. 18C, potting material is then applied in order to form the outer package 50 of the residual current sensor component. FIG. 18C in this case shows a partial cross-sectional view along Q-Q only of the lower part of FIG. 18D. FIG. 18D shows a schematic plan view of the residual current component having the connections of the current conductors 20 and 22 protruding from the package 50 and the signal/power supply connections A1 to A4.

FIGS. 19A and 19B show a further example of a residual current sensor component with vertical detection and an internal magnetic field concentrator, in which a package cast entirely from a potting material is cast into a further package. FIG. 19A in this case shows a schematic plan view, and FIG. 19B shows a schematic cross-sectional view along Q-Q in FIG. 19A. A magnetic field sensor chip 30 having a magnetic field sensor 32 is mounted on a lead frame, for example on a chip pad thereof. The lead frame comprises the two current conductors 20 and 22 and signal/power supply connections A1 to A5. The magnetic field sensor chip 30 and the lead frame having the two current conductors 20 and 22 are packaged in a package 150, which consists of a potting material. As shown in FIG. 19B, a magnetic field concentrator 44 is provided on the outer surface of the package 150 and surrounds the two conductors 20 and 22 on three sides and extends in a U-shape from the top of the magnetic field sensor 32 to the bottom thereof. As may be seen in FIG. 19B, the ends of the limbs of the U-shaped magnetic field concentrator 44 extend obliquely with respect to the magnetic field sensor. The ends of the magnetic field concentrator may also have a corresponding shape in other examples. The package 150 may in this case be considered to be an inner package in the form of an insulating component. The magnetic field concentrator 44 is formed on an outer surface of this insulating component. Furthermore, a further package 152, which comprises a potting compound, is provided above the magnetic field concentrator 44. This “outer” package 152 packages the magnetic field concentrator and parts of the inner package 50, and thus also the magnetic field sensor. The inner and/or outer package 152 may be cast in the usual way using potting material.

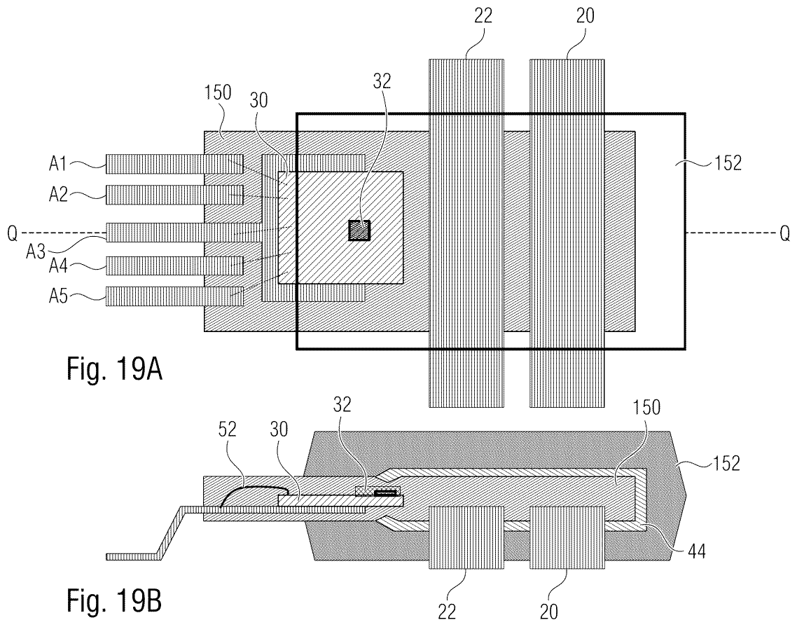

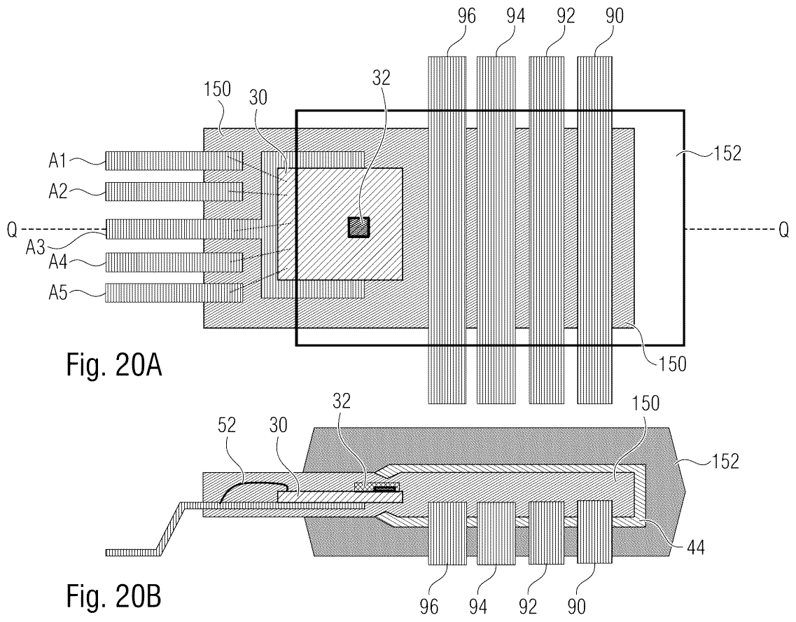

FIGS. 20A and 20B show a schematic plan view and a schematic cross-sectional view along Q-Q in FIG. 20A of a corresponding component, which differs from the component shown in FIGS. 19A and 19B only in that four current conductors 90 to 96 are provided, these being arranged in the package 150, 152. The magnetic field concentrator 44 accordingly surrounds the four current conductors 90 to 96 on three sides thereof. For the rest, reference is made to the above statements with regard to FIGS. 19A and 19B and to the above statements with regard to examples of residual current sensor components with vertical detection having four conductors.

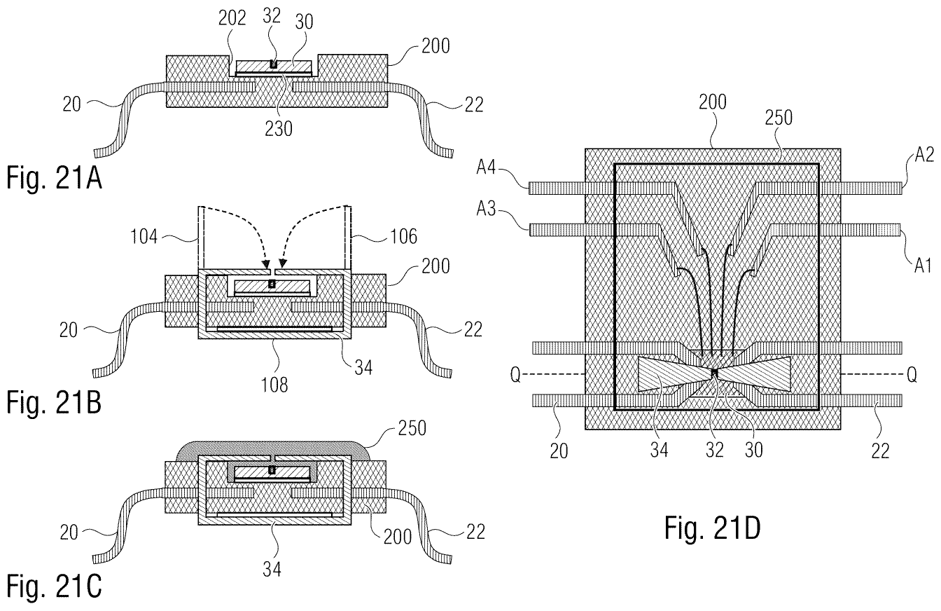

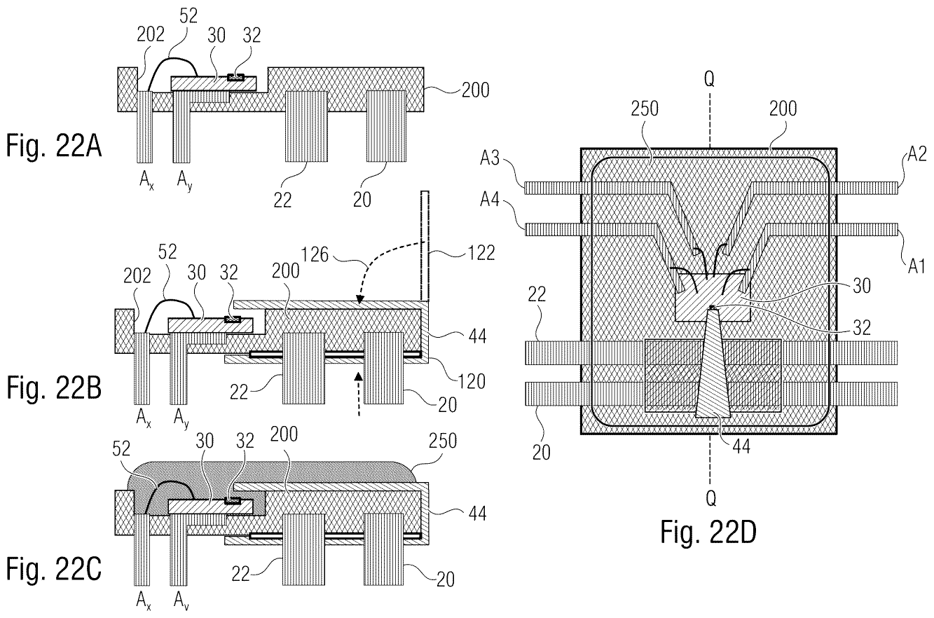

Examples of the following disclosure are described below, with reference to FIGS. 21A-21D and FIGS. 22A-22D, in which the residual current sensor component comprises an insulating plate-shaped carrier and a potting material, wherein parts of the potting material and parts of the carrier are exposed to the outside and constitute an outer boundary of the residual current sensor component, and thus a package thereof. One example of a residual current sensor component with horizontal detection is also described, with reference to a method for producing same, with reference to FIGS. 21A-21D, whereas a corresponding description of one example of a residual current sensor component with vertical detection is given with reference to FIGS. 22A-22D.

FIGS. 21A and 21B show schematic cross-sectional illustrations of an intermediate product during the production of a corresponding component, whereas FIG. 21C shows a schematic cross-sectional illustration along Q-Q in FIG. 21D, and FIG. 21D shows a schematic plan view. As shown in FIG. 21A, the intermediate product has an insulating plate-shaped carrier 200 that has a recess 202 in a main surface thereof, the upper surface in FIG. 21A, with a magnetic field sensor chip 30 having a magnetic field sensor 32 being arranged in the recess. A lead frame having conductors 20 and 22 is also arranged in the insulating component 200. The magnetic field sensor chip 30 is for example mounted in the recess 202 by way of an adhesive layer 230. The insulating plate-shaped carrier 200 also has openings (not shown in FIG. 21A) through which parts of a preform of a magnetic field concentrator are able to be pushed. The magnetic field concentrator may in this case have a preform as has been described above with reference to FIG. 14B, namely a U-shape with limbs 104 and 106 and a bottom 108. The limbs 104 and 106 are pushed through the openings from a side of the plate-shaped carrier 200 that is remote from the magnetic field sensor chip, such that they protrude on the side facing the magnetic field sensor chip 30, as shown by dashed lines in FIG. 21B. An adhesive layer may again be provided between the bottom 108 and the facing side of the plate-shaped carrier 200. The upper parts of the limbs 104 and 106 are then bent inward, as has been described above with reference to FIG. 14B, so as to result in the magnetic field concentrator 34 shown in FIG. 21B. This is followed by application of a potting material 250 that covers the magnetic field sensor chip 30, and thus the magnetic field sensor, and at least parts of the magnetic field concentrator 34. In the example shown, the potting material covers the inwardly bent parts of the limbs 104 and 106. The magnetic field concentrator surrounds the adjacently arranged sections of the at least two current conductors on three sides thereof, in a manner as has been described above with reference to examples of the present disclosure. The plate-shaped insulating carrier may in this case be connected to parts of the lead frame via bonding wires or by way of flip-chip connections. In the examples of the present disclosure, the insulating plate-shaped carrier may consist of a suitable insulating material, for example a preformed plastic, a ceramic material, or another suitable substrate material.

FIGS. 22A-22D show corresponding illustrations with regard to a residual current sensor component with vertical detection. An intermediate product shown in FIG. 22A comprises an insulating plate-shaped carrier 200, which has a recess 202 in a main surface thereof, the upper surface thereof in FIG. 22A, with a magnetic field sensor chip 30 having a magnetic field sensor 32 being arranged in the recess. Connections of the magnetic field sensor chip 30 may again be connected to connection regions of a lead frame in a suitable manner by bonding wires 52 or using flip-chip connections. The lead frame is mounted on or carried by the insulating plate-shaped carrier 200. The lead frame again comprises current conductors 20 and 22 and signal/power supply connections A1 to A4, which are designated Ax and Ay in FIGS. 22A-22C. Starting from the intermediate product shown in FIG. 22A, a preform of a magnetic field concentrator is mounted on the insulating plate-shaped carrier 200 from the side remote from the magnetic field sensor chip 30, for example by way of an adhesive layer. The preform of the magnetic field concentrator again has a right-angled shape, with a horizontal, lateral section 120 and a vertical section, which is illustrated in partially dashed form in its initial shape in FIG. 22B. After the preform of the magnetic field concentrator has been mounted, the upper part of the vertical part 122 is bent inward toward the magnetic field sensor 32, as indicated by an arrow 126 in FIG. 22B. This results in the formation of a substantially U-shaped magnetic field concentrator 44, which may have a shape corresponding to that of the magnetic field concentrator shown in FIG. 2C, wherein reference is made to the above statements with regard to examples of the present disclosure with regard to further details of such a magnetic field concentrator.

After the magnetic field concentrator has been mounted, a potting material is then applied, which covers the magnetic field sensor chip 30, and thus the magnetic field sensor 32, and at least parts of the magnetic field concentrator 44. A schematic cross-sectional view (along Q-Q in FIG. 22D) and a schematic plan view of the resulting component are shown in FIGS. 22C and 22D. These views illustrate the finished component, wherein it may be seen that parts of the potting material 250 and parts of the carrier 200 are exposed to the outside and constitute an outer boundary of the residual current sensor component that is shown.

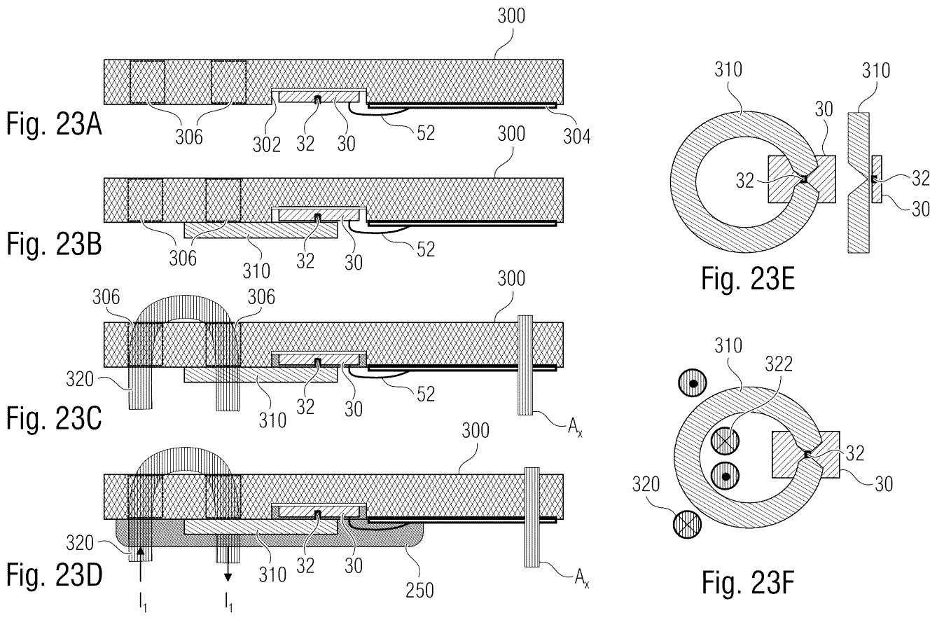

Further examples of residual current sensor components having an insulating plate-shaped carrier and magnetic field sensor, in which parts of the potting material and parts of the carrier are exposed to the outside and constitute an outer boundary of the residual current sensor component, will now be explained with reference to FIGS. 23-26.

FIG. 23A shows a schematic cross-sectional view of an intermediate product comprising an insulating plate-shaped carrier 300 and a magnetic field sensor chip 30 that is arranged in a recess 302 in a main surface of the plate-shaped carrier 300. The magnetic field sensor chip 30 may be mounted in the recess 302 via an adhesive layer and be conductively connected to a lead frame 304, which is formed on the insulating plate-shaped carrier 300, via bonding wires 52 or flip-chip connections. The insulating plate-shaped carrier 300 has holes 306 (e.g., a plurality of first holes and a plurality of second holes) that pass through it between its main surfaces. As shown in FIG. 23B, a magnetic field concentrator 310 is mounted on the insulating plate-shaped carrier. As may be seen in the left-hand part of FIG. 23E, which is a schematic plan view of the magnetic field concentrator 310 and the magnetic field sensor chip 30, the magnetic field concentrator 310 is substantially annular and has sections that taper toward the magnetic field sensor 32. The magnetic field concentrator may be interrupted or may have a region of low width in the region of the magnetic field sensor 32. As shown in the right-hand part of FIG. 23E, the sections of the magnetic field concentrator 310 that lead to the magnetic field sensor 32 may also be tapered toward the magnetic field sensor in the thickness direction, that is to say perpendicular to the chip plane of the magnetic field sensor chip 30, that is to say in the vertical direction. The corresponding sections of the magnetic field concentrator 310 may thus be tapered in the vertical and/or lateral direction.

Starting from the state shown in FIG. 23B, in which the magnetic field concentrator 310 is mounted on the main surface of the plate-shaped carrier 300 in order to be arranged, with respect to the magnetic field sensor chip 30, as shown in FIG. 23E, two U-shaped current conductors are now inserted into the holes 306, such that each conductor extends through a respective first hole (e.g., of a plurality of first holes) from a first main surface of the carrier 300 to a second, opposing main surface of the carrier 300 and then extends through a respective second hole (e.g., of a plurality of second holes) from the second main surface of the carrier 300 back to the first main surface of the carrier 300. This is illustrated in FIG. 23C, which shows a conductor 320 that extends through the left hole from the lower main surface of the carrier 300 to the upper main surface of the carrier 300, is bent there, and then extends through the right hole 306 of the carrier 300 from the upper surface thereof to the lower surface thereof. A current flow In may take place through the current conductor 320 in the direction indicated by arrows in FIG. 23D. A second conductor 322 is guided through corresponding further holes 306 in the carrier 300, as may be seen from the plan view in FIG. 23F. Two of the holes 306 are adjacent to one another such that the conductors 320 and 322 have adjacently arranged sections through which currents with opposing mathematical signs flow. The magnetic field concentrator 310 is configured to surround these two sections of the current conductors 320 and 322, as may be seen in FIG. 23F.

After the current conductors have been inserted into the openings 306, a potting material 250 is applied to the main surface of the carrier 300 in which the recess 302 is formed, such that it covers the magnetic field sensor chip 30, and thus the magnetic field sensor 32, and at least parts of the magnetic field concentrator 310. In the example shown in FIG. 23D, the potting material is also provided above the holes 306 on the main surface of the insulating carrier 300 in which the recess 302 is formed, such that this potting material forms a package for those parts of the current conductors 320, 322 that are arranged in the holes, for the magnetic field concentrator 310 and for the magnetic field sensor chip 30. As illustrated schematically in FIGS. 23C and 23D, further parts of the lead frame 304 may be formed in the plate-shaped carrier 300.

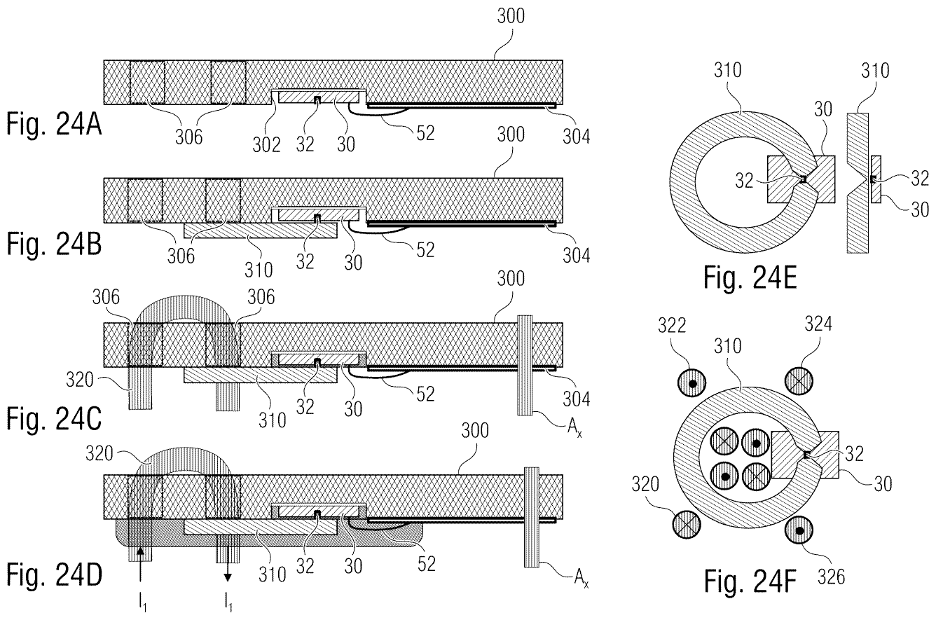

FIGS. 24A-24F show corresponding illustrations of one example of a residual current sensor component having four current conductors, wherein the only difference between the example shown in FIGS. 24A-24F and the example shown in FIGS. 23A to 23F is that four conductors are provided instead of the two conductors. Another description of the corresponding features is therefore omitted. As shown in FIG. 24F, the magnetic field concentrator 310 is in this case configured to surround four adjacently arranged sections of four current conductors 320, 322, 324 and 326, which are inserted through corresponding holes 306 in the body 300. The magnetic field concentrator 310 is thus configured to concentrate a magnetic field generated by currents through these conductors onto the magnetic field sensor 32.

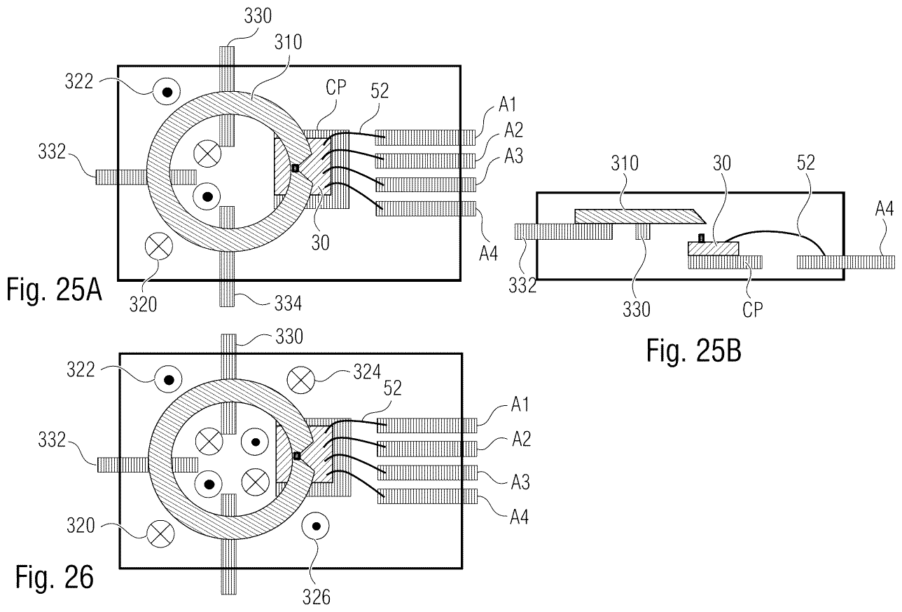

FIGS. 25A and 25B schematically show a plan view of one example of a component, as has been described above with reference to FIGS. 23A-23F, for illustrating aspects relating to the lead frame 304. The lead frame 304 may thus comprise for example four signal/power supply connections A1 to A4, a chip pad, CP, on which the magnetic field sensor chip 30 is arranged, and support elements 330, 332 and 334, which may serve to support the magnetic field concentrator. It is pointed out in this respect that FIGS. 25A and 25B are purely schematic for the purpose of describing the corresponding features of the lead frame, with further details being omitted from these illustrations. As may be seen in FIG. 25B, the support elements 330, 332, 334 may be configured to hold the magnetic field concentrator 310 above the magnetic field sensor chip 30. FIG. 26 shows a corresponding schematic plan view for illustrating features of the lead frame 304 in connection with a residual current sensor component comprising four current conductors, as has been described above with reference to FIGS. 24A-24F.

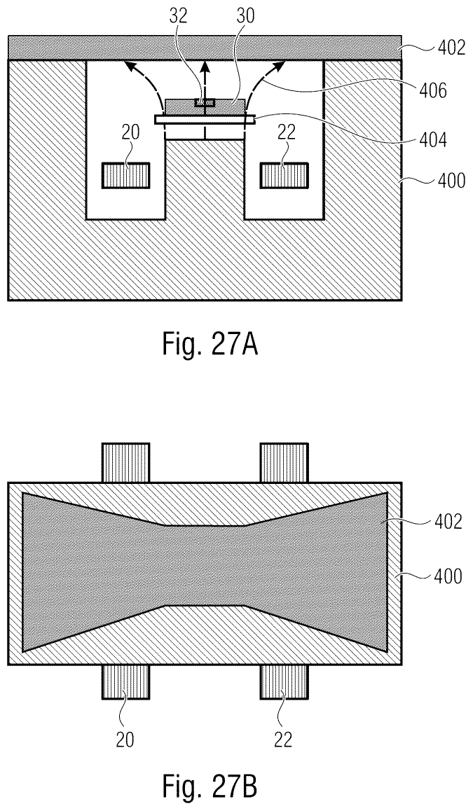

FIGS. 27A and 27B show a further example of a residual current sensor component with vertical detection. FIG. 27A in this case shows a schematic cross-sectional view, whereas FIG. 27B shows a schematic plan view. In this example, the magnetic field concentrator is formed by a ferrite core 400 having an upper plate 402. Two current conductors 20 and 22 are arranged, with respect to the ferrite core 400, for example by way of an insulator, such that magnetic fields generated by currents flowing through the conductors 20 and 22, through the ferrite core 400 and the upper cover 402 are concentrated onto the magnetic field sensor 32 of the magnetic field sensor chip 30, as shown by arrows 406 in FIG. 27A. The ferrite core 400 is symmetrical and has a central elevation on which the magnetic field sensor chip 30 is arranged. The magnetic field sensor chip may in turn be arranged on a lead frame 404. The arrangement shown in FIGS. 27A and 27B may in turn be packaged by a potting material, such that the package is formed entirely from the potting material. Signal/power supply connections of the magnetic field sensor chip 30 and connections of the two current conductors 20 and 22 may in turn protrude from the package, in a known manner.

In examples of residual current sensor components according to the present disclosure, a part of the magnetic field concentrator is formed on a surface of the magnetic field sensor chip. This part, together with another part that is not formed on the surface of the magnetic field sensor chip, forms the overall magnetic field concentrator. Examples of the present disclosure comprise a current sensor component in which the magnetic field from only one current conductor is concentrated onto a magnetic field sensor using a corresponding magnetic field concentrator. Examples of the present disclosure may thus have a structure as shown in FIGS. 9A and 9B, 17A-17D and 18A-18D, wherein, instead of the two current conductors, only a single current conductor is formed in the package. Such a current sensor component may accordingly be used to detect a current flowing through the current conductor by concentrating the magnetic field generated by the current onto the magnetic field sensor by way of the magnetic field concentrator and detecting it by way of the magnetic field sensor. For the rest, with regard to further features of such a current sensor component, reference is made to the above descriptions of FIGS. 9A and 9B, 17A-17D and 18A-18D, wherein the reference there to two current conductors is to be replaced in each case by a reference to one current conductor.

Examples of the present disclosure thus provide a residual current sensor component having a package body made of a potting material without a prefabricated shell or covering. There is thus no use of a shell into which various sub-components, including the magnetic field concentrator, are inserted. According to the present disclosure, the components are cast without another lid or another shell element being used. According to the disclosure, the potting material defines the package body and its surface. In examples of the disclosure, the potting material constitutes an at least partially all-round boundary of the component. In examples, the definition whereby a magnetic field concentrator at least partially surrounds adjacently arranged sections of at least two current conductors means that it at least partially surrounds the current conductors on at least three sides thereof. Examples of the disclosure thus relate to an integrated package that is fully integrated in such a way that it is able to be produced using standard semiconductor processes. In examples of the disclosure, the current is carried through the magnetic core, that is to say the magnetic field concentrator, such that the current-carrying current conductors generate magnetic field components in the magnetic field concentrator that balance out when the currents are correspondingly uniform, such that no output signal is generated. If the currents differ, a difference signal indicating a residual current is generated. In examples of the disclosure, the corresponding current conductors may be part of a lead frame, and so not only the current conductors but also signal lines and power supply lines are able to be integrated as part of a lead frame in a conventional manner.

In examples, the main components of the current sensor component, in particular of the residual current sensor component, are only the magnetic field sensor chip, the lead frame, the magnetic field concentrator and the package made of potting material, wherein further or other package components are not provided. In other examples, a plate-shaped carrier is provided as only an additional package component and forms the package together with the potting material. Further package components are not provided.

Aspects of the present disclosure are set forth below:

Aspect 1: A residual current sensor component, having the following features:
a package formed entirely from a potting material that is exposed to the outside and constitutes an outer boundary of the package;
at least one magnetic field sensor arranged in the package;
at least two current conductors having sections arranged adjacently in the package;
a magnetic field concentrator that at least partially surrounds the adjacently arranged sections of the at least two current conductors and is configured to concentrate a magnetic field generated by currents flowing through the at least two current conductors onto the magnetic field sensor,
wherein the magnetic field concentrator is arranged at least partially in the potting material or is mounted on an outer surface of the package.

Aspect 2: A residual current sensor component, having the following features:
an insulating plate-shaped carrier;
a magnetic field sensor;
at least two current conductors having adjacently arranged sections;
a magnetic field concentrator that at least partially surrounds the adjacently arranged sections of the at least two current conductors and is configured to concentrate a magnetic field generated by currents flowing through the at least two current conductors onto the magnetic field sensor,
wherein the insulating plate-shaped carrier carries the magnetic field sensor, the at least two current conductors and the magnetic field concentrator,
wherein a potting material is applied to a main surface of the insulating plate-shaped carrier and covers the magnetic field sensor and at least parts of the magnetic field concentrator, and
wherein parts of the potting material and parts of the carrier are exposed to the outside and constitute an outer boundary of the residual current sensor component.

Aspect 3: The residual current sensor component according to aspect 1 or 2, in which sections of the magnetic field concentrator taper toward the magnetic field sensor.

Aspect 4: The residual current sensor component according to one of aspects 1 to 3, in which the at least two current conductors comprise four current conductors, wherein the magnetic field concentrator at least partially surrounds the adjacently arranged sections of the four current conductors.

Aspect 5: The residual current sensor component according to one of aspects 1 to 4, in which the at least two current conductors are parts of a lead frame.

Aspect 6: The residual current sensor component according to one of aspects 1 to 5, in which those sections of the at least two current conductors that are arranged in the package run straight through the package.

Aspect 7: The residual current sensor component according to one of aspects 1 to 6, in which the magnetic field concentrator is arranged entirely in the potting material.

Aspect 8: The residual current sensor component according to one of aspects 1 to 7, in which the magnetic field sensor is configured to detect a magnetic field in a direction in which the sections of the at least two current conductors are arranged adjacently, wherein the magnetic field sensor overlaps a region between the at least two current conductors in plan view of the adjacently arranged sections of the at least two current conductors and is preferably arranged so as to be centered with respect to the at least two current conductors.

Aspect 9: The residual current sensor component according to aspect 8, in which the magnetic field concentrator has first sections that extend away from the magnetic field sensor in opposing directions, second sections that are guided externally around the outer of the at least two current conductors, and a third section that extends between the second sections of the magnetic field concentrator on the side of the current conductors that is remote from the first sections.

Aspect 10: The residual current sensor component according to one of aspects 1 to 7, in which the magnetic field sensor is configured to detect a magnetic field in a direction perpendicular to a direction in which the sections of the at least two current conductors are arranged adjacently, wherein the magnetic field sensor is arranged on an outer side of one of the sections of the at least two current conductors that are arranged adjacently.

Aspect 11: The residual current sensor component according to aspect 10, in which the magnetic field concentrator, starting from the magnetic field sensor, has sections that extend transversely over the adjacently arranged sections of the at least two conductors and that are arranged on opposing sides of the at least two conductors.

Aspect 12: The residual current sensor component according to aspect 10 or 11, in which the magnetic field sensor is a first magnetic field sensor, and which comprises a second magnetic field sensor that is arranged on an outer side of another of the sections of the at least two current conductors that are arranged adjacently.

Aspect 13: The residual current sensor component according to one of aspects 1 to 12 when referring back to aspect 1, having an insulating component in which the adjacently arranged sections of the at least two current conductors are arranged, wherein the magnetic field concentrator is formed on the outer surface of the insulating component, and wherein the potting material of the package is provided so as to cover the magnetic field sensor and at least parts of the magnetic field concentrator and of the insulating component.

Aspect 14: The residual current sensor component according to one of aspects 2 and 3 to 12 when referring back to aspect 2, in which the insulating plate-shaped carrier is an insulating component in which the magnetic field sensor and the adjacently arranged sections of the at least two current conductors are arranged.

Aspect 15: The residual current sensor component according to aspect 13 or 14, in which sections of the magnetic field concentrator are bent around the insulating component.

Aspect 16: The residual current sensor component according to one of aspects 1 to 15, in which sections of the magnetic field concentrator are formed on a chip surface of the magnetic field sensor.

Aspect 17: The residual current sensor component according to one of aspects 1, 2 to 13, 15 and 16 when referring back to aspect 1, in which the magnetic field concentrator is clamped onto the package as a clip.

Aspect 18: The residual current sensor component according to one of aspects 2 and 3 or 4 when referring back to aspect 2, in which the insulating plate-shaped carrier has a recess in which the magnetic field sensor is arranged, wherein the insulating plate-shaped carrier furthermore has holes through which the at least two current conductors are guided, wherein each current conductor extends through a respective first hole from a first main surface of the insulating plate-shaped carrier to a second main surface of the insulating plate-shaped carrier, and then extends through a respective second hole from the second main surface back to the first main surface, wherein the magnetic field concentrator extends from the magnetic field sensor through a region between the first and second holes and back to the magnetic field sensor on the side of the first main surface of the insulating plate-shaped carrier, wherein the potting material is provided on the magnetic field concentrator on the side of the first main surface.

Aspect 19: The residual current sensor component according to aspect 18, in which the potting material is provided above the holes on the first surface of the insulating carrier.

Aspect 20: A current sensor component, having the following features:
a package;
at least one magnetic field sensor chip arranged in the package and having a magnetic field sensor;
at least one current conductor having a section arranged in the package;
a magnetic field concentrator that at least partially surrounds the section of the current conductor arranged in the package and is configured to concentrate a magnetic field generated by a current flowing through the at least one current conductor onto the magnetic field sensor,
wherein part of the magnetic field concentrator is formed on the chip surface of the magnetic field sensor chip.

Aspect 21: The current sensor component according to aspect 20, in which the magnetic field concentrator is arranged at least partially in a potting material of the package or is mounted on an outer surface of the potting material.

Aspect 22: The current sensor component according to aspect 20 or 21, in which main surfaces of the magnetic field sensor chip run parallel to a magnetic field sensor chip plane, wherein the magnetic field sensor is configured to detect a magnetic field perpendicular to the magnetic field sensor chip plane, and wherein the magnetic field concentrator at least partially surrounds the at least one current conductor on three sides thereof.

Aspect 23: The current sensor component according to aspect 20 or 21, in which main surfaces of the magnetic field sensor chip run parallel to a magnetic field sensor chip plane, wherein the magnetic field sensor is configured to detect a magnetic field parallel to the magnetic field sensor chip plane, and wherein the magnetic field concentrator at least partially surrounds the at least one current conductor on four sides thereof.

Aspect 24: A method for producing a residual current sensor component according to aspect 15, having the following features:
providing an intermediate product comprising an insulating component, the magnetic field sensor and at least two current conductors;
providing a preform of the magnetic field concentrator;
mounting the preform of the magnetic field concentrator on the intermediate product and bending at least one section of the preform of the magnetic field concentrator toward the magnetic field sensor; and
applying the potting material so as to cover at least the magnetic field concentrator.

Aspect 25: A method for producing a residual current sensor component according to one of aspects 1, 3 to 6 when referring to aspect 1, and 17, having the following features: producing a package in which the magnetic field sensor and the at least two current conductors are packaged using the potting material; applying the magnetic field concentrator to an outer surface of the potting material.

Aspect 26: The method according to aspect 25, comprising providing the magnetic field concentrator as a clip and clamping the magnetic field concentrator onto the package, or comprising providing a preform of the magnetic field concentrator and bending a part of the preform of the magnetic field concentrator around the package.

Aspect 27: A method for producing a residual current sensor component according to aspect 18, having the following features:
producing an intermediate product comprising the insulating plate-shaped carrier having the holes, the magnetic field sensor and the magnetic field concentrator;
inserting the at least two current conductors into the holes; and
applying the potting material at least above the magnetic field concentrator.

Aspect 28: The method according to aspect 27, in which the potting material is also applied above the holes on the first surface of the insulating carrier.

Even though some aspects of the present disclosure have been described as features in conjunction with a device, it is evident that such a description may likewise be considered to be a description of corresponding method features. Even though some aspects have been described as features in conjunction with a method, it is evident that such a description may also be considered to be a description of corresponding features of a device or of the functionality of a device.

In the above detailed description, in some cases different features have been grouped together in examples in order to rationalize the disclosure. This kind of disclosure should not be interpreted as being intended for the claimed examples to have more features than specified expressly in each claim. Rather, as set forth in the following claims, the subject matter may be present in less than all of the features of a single disclosed example. The following claims are therefore hereby incorporated into the detailed description, wherein each claim may exist as a standalone separate example. While each claim may exist as a standalone separate example, it is pointed out that, although dependent claims in the claims refer back to a specific combination with one or more other claims, other examples also comprise a combination of dependent claims with the subject matter of any other dependent claim or a combination of any feature with other dependent or independent claims. Such combinations are included, unless it is stated that a specific combination is not intended. It is furthermore also intended for a combination of features of a claim with any other independent claim to be included, even if this claim is not directly dependent on the independent claim.

The examples described above merely illustrate the principles of the present disclosure. It should be understood that modifications and variations of the arrangements and of the details that are described are obvious to those skilled in the art. Therefore, the disclosure is intended to be limited only by the appended patent claims and not by the specific details that are presented for the purpose of describing and explaining the examples.

1. A residual current sensor component, comprising:
a package formed entirely from a potting material that is exposed to an outside and constitutes an outer boundary of the package;
at least one magnetic field sensor arranged in the package;
at least two current conductors having adjacently arranged sections arranged adjacently in the package; and
a magnetic field concentrator that at least partially surrounds the adjacently arranged sections of the at least two current conductors and is configured to concentrate a magnetic field generated by currents flowing through the at least two current conductors onto the magnetic field sensor,
wherein the magnetic field concentrator is arranged at least partially in the potting material or is mounted on an outer surface of the package.

2. A residual current sensor component, comprising:
an insulating plate-shaped carrier;
a magnetic field sensor;
at least two current conductors having adjacently arranged sections; and
a magnetic field concentrator that at least partially surrounds the adjacently arranged sections of the at least two current conductors and is configured to concentrate a magnetic field generated by currents flowing through the at least two current conductors onto the magnetic field sensor,
wherein the insulating plate-shaped carrier carries the magnetic field sensor, the at least two current conductors and the magnetic field concentrator,
wherein a potting material is applied to a main surface of the insulating plate-shaped carrier and covers the magnetic field sensor and at least parts of the magnetic field concentrator, and
wherein parts of the potting material and parts of the insulating plate-shaped carrier are exposed to an outside and constitute an outer boundary of the residual current sensor component.

3. The residual current sensor component as claimed in claim 2, wherein sections of the magnetic field concentrator taper toward the magnetic field sensor.

3. The residual current sensor component as claimed in claim 2, wherein the at least two current conductors comprise four current conductors, and wherein the magnetic field concentrator at least partially surrounds the adjacently arranged sections of the four current conductors.

5. The residual current sensor component as claimed in claim 2, wherein the at least two current conductors are parts of a lead frame.

6. The residual current sensor component as claimed in claim 1, wherein sections of the at least two current conductors that are arranged in the package run straight through the package.

7. The residual current sensor component as claimed in claim 2, wherein the magnetic field concentrator is arranged entirely in the potting material.

8. The residual current sensor component as claimed in claim 2, wherein the magnetic field sensor is configured to detect a magnetic field in a direction in which the adjacently arranged sections of the at least two current conductors are arranged adjacently, and
wherein the magnetic field sensor overlaps a region between the at least two current conductors in plan view of the adjacently arranged sections of the at least two current conductors and is arranged so as to be centered with respect to the at least two current conductors.

9. The residual current sensor component as claimed in claim 8, wherein the magnetic field concentrator has first sections that extend away from the magnetic field sensor in opposing directions, second sections that are guided externally around the outer of the at least two current conductors, and a third section that extends between the second sections of the magnetic field concentrator on a side of the current conductors that is remote from the first sections.

10. The residual current sensor component as claimed in claim 2, wherein the magnetic field sensor is configured to detect a magnetic field in a direction perpendicular to a direction in which the adjacently arranged sections of the at least two current conductors are arranged adjacently, wherein the magnetic field sensor is arranged on an outer side of one of the adjacently arranged sections of the at least two current conductors that are arranged adjacently.

11. The residual current sensor component as claimed in claim 10, wherein the magnetic field concentrator, starting from the magnetic field sensor, has sections that extend transversely over the adjacently arranged sections of the at least two current conductors and that are arranged on opposing sides of the at least two current conductors.

12. The residual current sensor component as claimed in claim 10, wherein the magnetic field sensor is a first magnetic field sensor, and
wherein the residual current sensor component further comprises a second magnetic field sensor that is arranged on an outer side of another of the adjacently arranged sections of the at least two current conductors that are arranged adjacently.

13. The residual current sensor component as claimed in claim 1, further comprising:
an insulating component in which the adjacently arranged sections of the at least two current conductors are arranged, wherein the magnetic field concentrator is formed on an outer surface of the insulating component, and wherein the potting material of the package is provided so as to cover the magnetic field sensor and at least parts of the magnetic field concentrator and of the insulating component.

14. The residual current sensor component as claimed in claim 3, wherein the insulating plate-shaped carrier is an insulating component in which the magnetic field sensor and the adjacently arranged sections of the at least two current conductors are arranged.

15. The residual current sensor component as claimed in claim 13, wherein sections of the magnetic field concentrator are bent around the insulating component.

16. The residual current sensor component as claimed in claim 2, wherein sections of the magnetic field concentrator are formed on a chip surface of the magnetic field sensor.

17. The residual current sensor component as claimed in claim 1, wherein the magnetic field concentrator is clamped onto the package as a clip.

18. The residual current sensor component as claimed in claim 2, wherein the insulating plate-shaped carrier has a recess in which the magnetic field sensor is arranged,
wherein the insulating plate-shaped carrier has holes through which the at least two current conductors are guided,
wherein each current conductor extends through a respective first hole of a plurality of first holes from a first main surface of the insulating plate-shaped carrier to a second main surface of the insulating plate-shaped carrier, and then extends through a respective second hole of a plurality of second holes from the second main surface back to the first main surface,
wherein the magnetic field concentrator extends from the magnetic field sensor through a region between the respective first hole and the respective second hole and back to the magnetic field sensor on a side of the first main surface of the insulating plate-shaped carrier, and
wherein the potting material is provided on the magnetic field concentrator on the side of the first main surface.

19. The residual current sensor component as claimed in claim 18, wherein the potting material is provided above the holes on a first surface of the insulating plate-shaped carrier.

20. A current sensor component, comprising:
a package;
at least one magnetic field sensor chip arranged in the package and having a magnetic field sensor;
at least one current conductor having a section arranged in the package; and
a magnetic field concentrator that at least partially surrounds the section of the current conductor arranged in the package and is configured to concentrate a magnetic field generated by a current flowing through the at least one current conductor onto the magnetic field sensor,
wherein part of the magnetic field concentrator is formed on a chip surface of the magnetic field sensor chip.

21. The current sensor component as claimed in claim 20, wherein the magnetic field concentrator is arranged at least partially in a potting material of the package or is mounted on an outer surface of the potting material.

22. The current sensor component as claimed in claim 20, wherein main surfaces of the magnetic field sensor chip run parallel to a magnetic field sensor chip plane, wherein the magnetic field sensor is configured to detect a magnetic field perpendicular to the magnetic field sensor chip plane, and wherein the magnetic field concentrator at least partially surrounds the at least one current conductor on three sides thereof.

23. The current sensor component as claimed in claim 20, wherein main surfaces of the magnetic field sensor chip run parallel to a magnetic field sensor chip plane, wherein the magnetic field sensor is configured to detect a magnetic field parallel to the magnetic field sensor chip plane, and wherein the magnetic field concentrator at least partially surrounds the at least one current conductor on four sides thereof.

24. A method for producing a residual current sensor component, the method comprising:
providing an intermediate product comprising a magnetic field sensor, at least two current conductors having adjacently arranged sections, and an insulating component in which the adjacently arranged sections of the at least two current conductors are arranged;
providing a preform of a magnetic field concentrator;
mounting the preform of the magnetic field concentrator on the intermediate product and bending at least one section of the preform of the magnetic field concentrator toward the magnetic field sensor; and
applying a potting material so as to cover at least the magnetic field concentrator.

25. A method for producing a residual current sensor component, the method comprising:
producing a package in which a magnetic field sensor and a at least two current conductors are packaged using potting material, the at least two current conductors having adjacently arranged sections arranged adjacently in the package; and
applying a magnetic field concentrator to an outer surface of the potting material, the magnetic field concentrator being clamped onto the package as a clip,
wherein the magnetic field concentrator is arranged such that the magnetic field concentrator at least partially surrounds the adjacently arranged sections of the at least two current conductors, and
wherein the magnetic field concentrator is configured to concentrate a magnetic field generated by currents flowing through the at least two current conductors onto the magnetic field sensor.

26. The method as claimed in claim 25, further comprising:
providing the magnetic field concentrator as a clip and clamping the magnetic field concentrator onto the package, or
providing a preform of the magnetic field concentrator and bending a part of the preform of the magnetic field concentrator around the package.

27. A method for producing a residual current sensor component, the method comprising:
producing an intermediate product comprising an insulating plate-shaped carrier having holes, a magnetic field sensor, and a magnetic field concentrator;
inserting at least two current conductors into the holes of the insulating plate-shaped carrier such that the magnetic field concentrator at least partially surrounds adjacently arranged sections of the at least two current conductors, wherein the magnetic field concentrator is configured to concentrate a magnetic field generated by currents flowing through the at least two current conductors onto the magnetic field sensor; and
applying a potting material at least above the magnetic field concentrator.

28. The method as claimed in claim 27, wherein the potting material is also applied above the holes on a first surface of the insulating plate-shaped carrier.
